(19) United States
(12) Patent Application Publication
(10) Pub. No.: US 2025/0393420 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: JANGMI KANG, Yongin-si (KR); MINKYU WOO, Yongin-si (KR); BYUNGCHANG YU, Yongin-si (KR); GEUNHO LEE, Yongin-si (KR)

(21) Appl. No.: 19/075,866

(22) Filed: Mar. 11, 2025

(30) Foreign Application Priority Data
Jun. 24, 2024 (KR) 10-2024-0081714

(51) Int. Cl. H10K 59/131; G09G 3/3233; H10K 59/121

(52) U.S. Cl. CPC H10K 59/131; H10K 59/1213; G09G 3/3233; G09G 2300/0426; G09G 2300/0842

(57) ABSTRACT

A display device includes: a first pixel circuit structure divided into a first area and a second area, a first guard trace electrically connected to the first area of the first pixel circuit structure, a second guard trace electrically connected to the second area of the first pixel circuit structure, a second pixel circuit structure adjacent to the first pixel circuit structure in a second direction, divided into a third area extending from the first area and a fourth area adjacent to the third area, and symmetrical to the first pixel circuit structure; a third guard trace electrically connected to the third area of the second pixel circuit structure, and a fourth guard trace electrically connected to the fourth area of the second pixel circuit structure.

This application claims priority to Korean Patent Application No. 10-2024-0081714, filed on Jun. 24, 2024, and all the benefits accruing therefrom under 35 U.S.C. § 119, the content of which in its entirety is herein incorporated by reference.

### BACKGROUND

### Field

Implementations of the inventive concept relate generally to a display device.

### Discussion of the Background

A display device includes pixel circuits and light emitting diodes. The pixel circuits are arranged side by side on a substrate, and signals and voltages are provided to the pixel circuits. The pixel circuits generate a driving current based on the signals and voltages, and the light-emitting diodes generate light based on the driving current.

### SUMMARY

Embodiments provide a display device.

A display device according to an embodiment includes: a first pixel circuit structure divided into a first area and a second area adjacent to the first area, a first guard trace electrically connected to the first area of the first pixel circuit structure and extending in a first direction, a second guard trace electrically connected to the second area of the first pixel circuit structure and extending in the first direction, a second pixel circuit structure adjacent to the first pixel circuit structure in a second direction intersecting the first direction, divided into a third area extending from the first area and a fourth area adjacent to the third area, and symmetrical to the first pixel circuit structure, a third guard trace electrically connected to the third area of the second pixel circuit structure and extending in the first direction, and a fourth guard trace electrically connected to the fourth area of the second pixel circuit structure and extending in the first direction.

In an embodiment, the second pixel circuit structure may be plane-symmetrical with the first pixel circuit structure with respect to a symmetry plane extending in the first direction and perpendicular to the second direction.

In an embodiment, no guard trace extending in the first direction may be disposed between the first guard trace and the third guard trace.

In an embodiment, no guard trace extending in the first direction may be disposed at a border between the first area and the third area.

In an embodiment, the first guard trace may be disposed in the first area and adjacent to the second area.

In an embodiment, the second guard trace may be disposed in the second area and adjacent to the first area.

In an embodiment, the third guard trace may be disposed in the third area and adjacent to the fourth area, and the fourth guard trace may be disposed in the fourth area and adjacent to the third area.

In an embodiment, the first pixel circuit structure may include a 1-1 transistor, a 1-2 transistor, a 1-3 transistor, and a 1-4 transistor, the 1-1 transistor, the 1-2 transistor, and the 1-3 transistor may be disposed in the first area, and the 1-4 transistor may be disposed in the second area.

In an embodiment, the second pixel circuit structure may include a 2-1 transistor, a 2-2 transistor, a 2-3 transistor, and a 2-4 transistor, the 2-1 transistor, the 2-2 transistor, and the 2-3 transistor may be disposed in the third area, and the 2-4 transistor may be disposed in the fourth area.

In an embodiment, the 1-1 transistor may be symmetrical to the 2-1 transistor, the 1-2 transistor may be symmetrical to the 2-2 transistor, the 1-3 transistor may be symmetrical to the 2-3 transistor, and the 1-4 transistor may be symmetrical to the 2-4 transistor.

In an embodiment, a first high power voltage may be provided to a back gate terminal of each of the 1-1 transistor, the 1-2 transistor, and the 1-3 transistor, and a second high power voltage different from the first high power voltage may be provided to a back gate terminal of the 1-4 transistor.

In an embodiment, the first high power voltage may be transmitted to the first guard trace through the first area, and the second high power voltage may be transmitted to the second guard trace through the second area.

In an embodiment, the 1-1 transistor, the 1-2 transistor, and the 1-3 transistor may be p-channel metal-oxide-semiconductor (“PMOS”) transistors, and the 1-4 transistor may be an n-channel metal-oxide-semiconductor (“NMOS”) transistor.

In an embodiment, the display device may further include a connecting guard trace electrically connecting the first guard trace and the third guard trace and extending in the second direction.

In an embodiment, the first pixel circuit structure may include active patterns disposed on a substrate, and connecting electrodes disposed on the active patterns and connected to the active patterns. The first guard trace may include a first lower guard trace disposed in a same layer as the active patterns, and a first upper guard trace disposed in a same layer as the connecting electrodes and connected to the first lower guard trace.

In an embodiment, the first lower guard trace may extend in the first direction.

In an embodiment, the first upper guard trace may be disposed in an island shape and contacts the first lower guard trace through a contact hole.

The display device may further include a third pixel circuit structure adjacent to the second pixel circuit structure in the second direction and symmetrical to the second pixel circuit structure.

Therefore, a display device according to embodiments of the present invention may include a first pixel circuit structure and a second pixel circuit structure. The second pixel circuit structure may be adjacent to the first pixel circuit structure in a second direction. In an embodiment, the second pixel circuit structure may be plane-symmetrical with the first pixel circuit structure with respect to a symmetry plane parallel to a first direction and perpendicular to the second direction.

Since the second pixel circuit structure is plane-symmetrical with the first pixel circuit structure with respect to the symmetry plane, a first area of the first pixel circuit structure and a third area of the second pixel circuit structure may be connected to each other. Accordingly, a first well may be formed continuously in the first and third areas. In other words, the first well may not be separated for the first area and the third area. Accordingly, no guard trace may be disposed at a border between the first and second pixel circuit structures, and the distance in the second direction between the first pixel circuit structure and the second pixel circuit structure may be shortened. Accordingly, the resolution of the display device can be effectively improved.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view illustrating a display device according to an embodiment of the present invention.

FIG. 2 is a cross-sectional view illustrating the display device of FIG. 1.

FIG. 3 is a circuit diagram illustrating a pixel included in the display device of FIG. 2.

FIG. 4 is a plan view illustrating a pixel circuit structure and a guard trace included in the display device of FIG. 2.

FIG. 5 is a plan view illustrating a first pixel circuit structure, a second pixel circuit structure, and a guard trace illustrated in FIG. 4.

FIG. 6 is a layout diagram illustrating the first pixel circuit structure, the second pixel circuit structure, and the guard trace of FIG. 5.

FIGS. 7, 8, 9, and 10 are layout diagrams illustrating the first pixel circuit structure, the second pixel circuit structure, and the guard trace of FIG. 6.

FIG. 11 is a cross-sectional view illustrating the first pixel circuit structure, the second pixel circuit structure, and the guard trace of FIG. 5.

FIG. 12 is a plan view illustrating a pixel circuit structure and a guard trace included in a display device according to another embodiment of the present invention.

FIG. 13 is a plan view illustrating a first pixel circuit structure, a second pixel circuit structure, and a guard trace illustrated in FIG. 12.

FIG. 14 is a layout diagram illustrating the first pixel circuit structure, the second pixel circuit structure, and the guard trace illustrated in FIG. 13.

FIGS. 15, 16, 17, and 18 are layout diagrams illustrating the first pixel circuit structure, the second pixel circuit structure, and the guard trace of FIG. 14.

FIG. 19 is a plan view illustrating a pixel circuit structure and a guard trace included in a display device according to still another embodiment of the present invention.

FIG. 20 is a cross-sectional view illustrating the display device of FIG. 19.

FIG. 21 is a circuit diagram illustrating a pixel included in the display device of FIG. 20.

FIG. 22 is a plan view illustrating a pixel circuit structure and a guard trace included in the display device of FIG. 20.

FIG. 23 is a plan view illustrating a first pixel circuit structure, a second pixel circuit structure, and a guard trace illustrated in FIG. 22.

FIG. 24 is a cross-sectional view illustrating the first pixel circuit structure, the second pixel circuit structure, and the guard trace illustrated in FIG. 23.

FIG. 25 is a diagram illustrating an electronic device including a display device of the present invention.

FIG. 26 is a perspective view illustrating an electronic device including a display device of the present invention.

FIG. 27 is a block diagram illustrating an electronic device according to an embodiment of the present invention.

FIG. 28 is a schematic diagram of an electronic device according to embodiments of the present invention.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third”, “1-1”, “1-2”, “2-1”, “2-2”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present. Similarly, it will be understood that when an element is referred to as being “connected to” another element, it can be directly connected to the other element or intervening elements may be present therebetween. In contrast, when an element is referred to as being “directly connected to” another element, there are no intervening elements present.

Illustrative, non-limiting embodiments will be more clearly understood from the following detailed description in conjunction with the accompanying drawings.

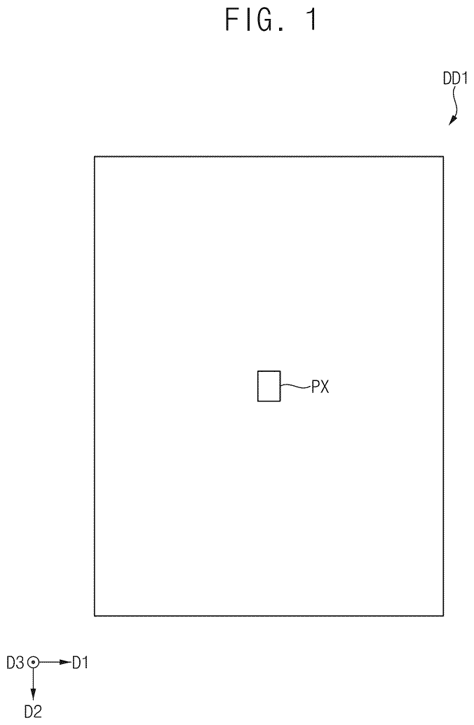

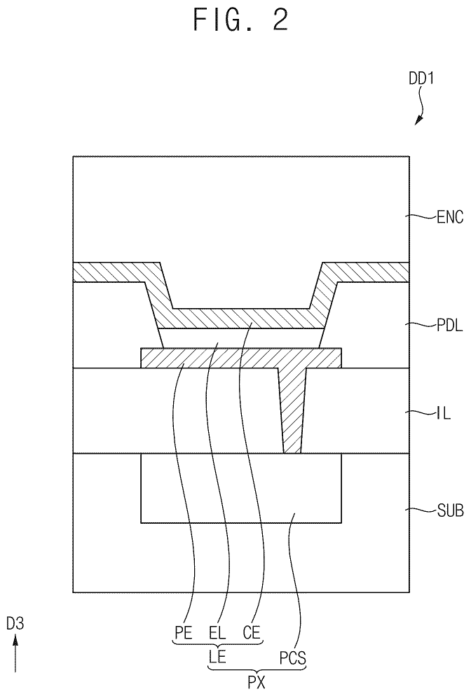

FIG. 1 is a plan view illustrating a display device according to an embodiment of the present invention. FIG. 2 is a cross-sectional view illustrating the display device of FIG. 1. As used herein, the “plan view” is a view in a thickness direction (i.e., third direction DR3) of the display device.

Referring to FIGS. 1 and 2, a display device DD1 according to an embodiment of the present invention may display an image in a third direction D3 through a display surface defined by a first direction D1 and a second direction D2 intersecting the first direction D1. For example, the second direction D2 may be perpendicular to the first direction D1, and the third direction D3 may be substantially parallel to a normal direction of the display surface.

The display device DD1 may include a substrate SUB, a pixel PX, an insulating layer IL, a pixel defining layer PDL, and an encapsulation layer ENC. The pixel PX may include a pixel circuit structure PCS and a light emitting diode structure LE, and the light emitting diode structure LE may include a pixel electrode PE, an emission layer EL, and a common electrode CE.

In an embodiment, the substrate SUB may be a semiconductor substrate. For example, the substrate SUB may include silicon, germanium, or silicon/germanium, or may be a silicon on isolation (SOI) substrate. In an embodiment, a plurality of active portions may be defined on the substrate SUB.

The pixel circuit structure PCS may be disposed on the substrate SUB. The pixel circuit structure PCS may include active patterns, gate electrodes, and lines, and accordingly, transistors may be implemented. The pixel circuit structure PCS may generate a driving current.

The insulating layer IL may be disposed on the substrate SUB. In an embodiment, the insulating layer IL may include an organic insulating material and/or an inorganic insulating material.

The pixel electrode P) may be disposed on the insulating layer IL. The pixel electrode PE may be electrically connected to the pixel circuit structure PCS and may receive the driving current. For example, the pixel electrode PE may be an anode electrode.

In an embodiment, the pixel electrode PE may include a metal, an alloy, a conductive metal oxide, or the like. For example, the pixel electrode PE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like.

The pixel defining layer PDL may be disposed on the pixel electrode PE. The pixel defining layer PDL may cover a peripheral portion of the pixel electrode PE and may expose a central portion of the pixel electrode PE. In an embodiment, the pixel defining layer PDL may include an organic material such as a polyimide-based resin, a photoresist, a polyacrylic-based resin, an acrylic resin, or an inorganic material such as silicon oxide and silicon nitride.

The emission layer EL may be disposed on the pixel electrode PE. The emission layer EL may generate light based on a voltage difference between the pixel electrode PE and the common electrode CE.

In an embodiment, the emission layer EL may include at least one of an organic light emitting material and a quantum dot.

In an embodiment, the organic light-emitting material may include a low-molecular organic compound or a high-molecular organic compound. Examples of the low-molecular organic compound may include copper phthalocyanine, N,N′-diphenylbenzidine, tris-(8-hydroxyquinoline)aluminum, and the like. Examples of the high-molecular organic compound may include poly(3,4-ethylenedioxythiophene), polyaniline, polyphenylenevinylene, polyfluorene, and the like, but the present invention is not limited thereto. These may be used alone or in combination with each other.

In an embodiment, the quantum dot may include a core including a group II-VI compound, a group III-V compound, a group IV-VI compound, a group IV element, a group IV compound, and a combination thereof. In an embodiment, the quantum dot may have a core-shell structure including the core and a shell surrounding the core. The shell may function as a protective layer to prevent chemical modification of the core to maintain semiconductor properties and as a charging layer to impart electrophoretic properties to the quantum dot.

The common electrode CE may be disposed on the emission layer EL. In an embodiment, the common electrode CE may include a metal, an alloy, a conductive metal oxide, or the like.

The encapsulation layer ENC may be disposed on the common electrode CE. The encapsulation layer ENC may have a structure in which an inorganic encapsulation layer and an organic encapsulation layer are intersected and stacked. The encapsulation layer ENC may protect the light emitting diode structure LE from the outside.

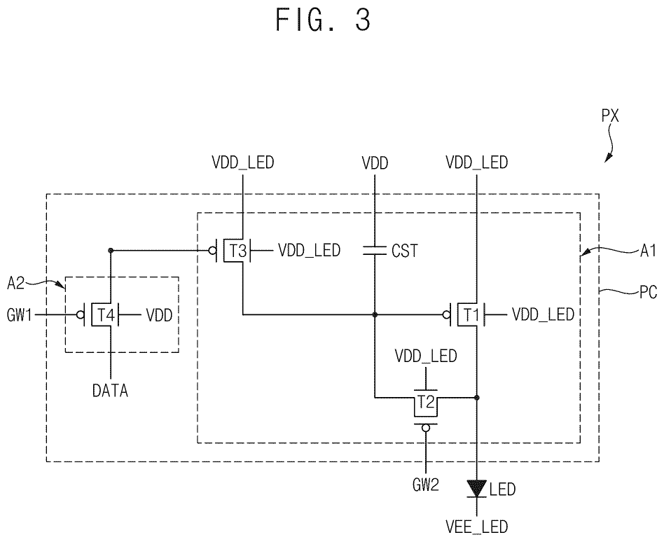

FIG. 3 is a circuit diagram illustrating a pixel included in the display device of FIG. 2.

Referring to FIG. 3, the pixel PX may include a pixel circuit PC and a light emitting diode LED. The pixel circuit PC may generate the driving current. The light emitting diode LED may be electrically connected to the pixel circuit PC and may emit light corresponding to the driving current.

The pixel circuit PC may include a first transistor T1, a second transistor T2, a third transistor T3, a fourth transistor T4, and a capacitor CST.

The first transistor T1 may include a gate terminal, a first terminal, a second terminal, and a back gate terminal. The gate terminal may be electrically connected to the capacitor CST, the first terminal may be electrically connected to a first high power voltage VDD_LED, and the second terminal may be electrically connected to the light emitting diode LED. The back gate terminal may receive the first high power voltage VDD_LED.

The second transistor T2 may include a gate terminal, a first terminal, a second terminal, and a back gate terminal. The gate terminal may be electrically connected to a second gate signal GW2, the first terminal may be electrically connected to the gate terminal of the first transistor T1, and the second terminal may be electrically connected to the second terminal of the first transistor T1. The back gate terminal may receive the first high power voltage VDD_LED.

The third transistor T3 may include a gate terminal, a first terminal, a second terminal, and a back gate terminal. The gate terminal may be electrically connected to the fourth transistor T4, the first terminal may receive the first high power voltage VDD_LED, and the second terminal may be electrically connected to the first transistor T1. The back gate terminal may receive the first high power voltage VDD_LED.

In an embodiment, each of the first to third transistors T1, T2, and T3 may be a PMOS transistor. However, the present invention is not limited thereto.

In an embodiment, the first transistor T1, the second transistor T2, and the third transistor T3 may be formed in a first area A1. For example, the first area A1 may be an area in which the first high power voltage VDD_LED is transmitted to the back gate terminals of the transistors. Accordingly, the first high power voltage VDD_LED may be transmitted to the back gate terminal of the first transistor T1, the back gate terminal of the second transistor T2, and the back gate terminal of the third transistor T3.

The fourth transistor T4 may include a gate terminal, a first terminal, a second terminal, and a back gate terminal. The gate terminal may be electrically connected to a first gate signal GW1, the first terminal may be electrically connected to a data voltage DATA, and the second terminal may be electrically connected to the third transistor T3. The back gate terminal may be electrically connected to a second high power voltage VDD.

In an embodiment, the fourth transistor T4 may be a PMOS transistor. However, the present invention is not limited thereto.

In an embodiment, the fourth transistor T4 may be formed in a second area A2. For example, the second area A2 may be an area in which the second high power voltage VDD is transmitted to the back gate terminal of the transistor. Accordingly, the second high power voltage VDD may be transmitted to the back gate terminal of the fourth transistor T4.

The capacitor CST may include a first terminal and a second terminal. The first terminal may be electrically connected to the second high power voltage VDD, and the second terminal may be electrically connected to the first transistor T1.

The light emitting diode LED may include a first terminal and a second terminal. The first terminal may be electrically connected to the first transistor T1, and the second terminal may be electrically connected to a low power voltage VEE_LED.

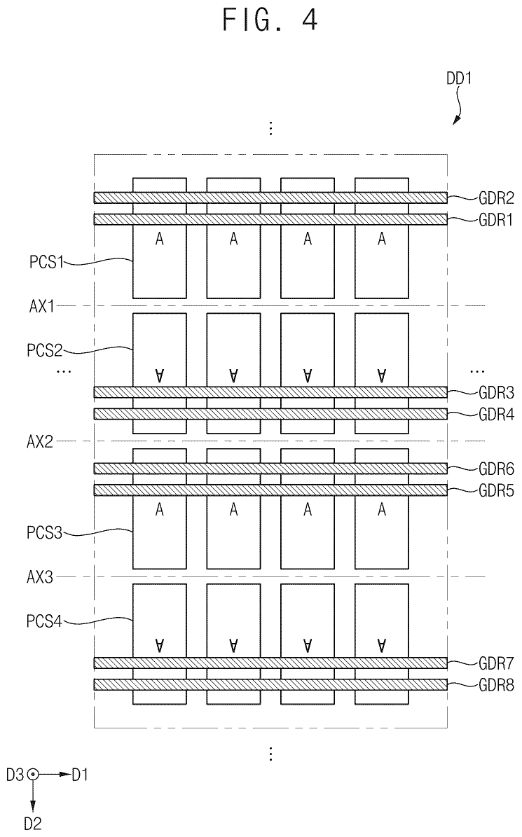

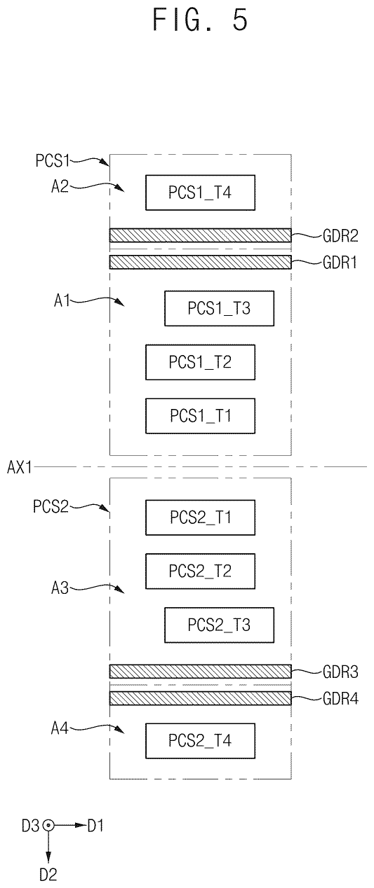

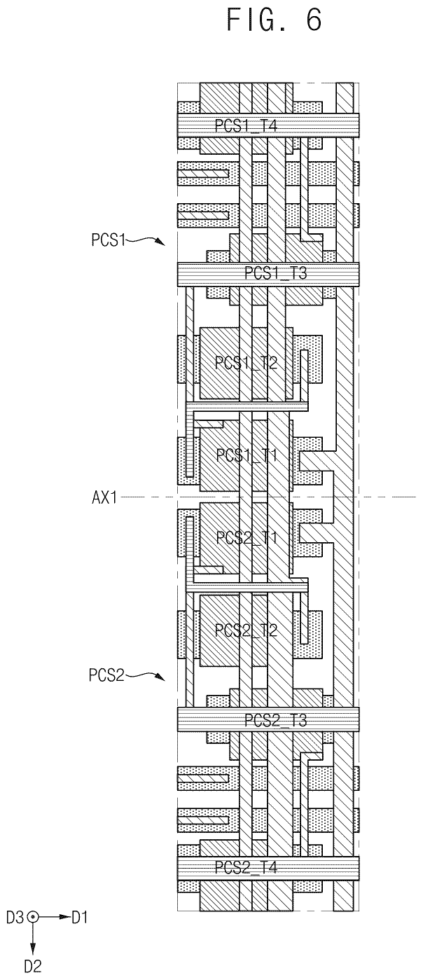

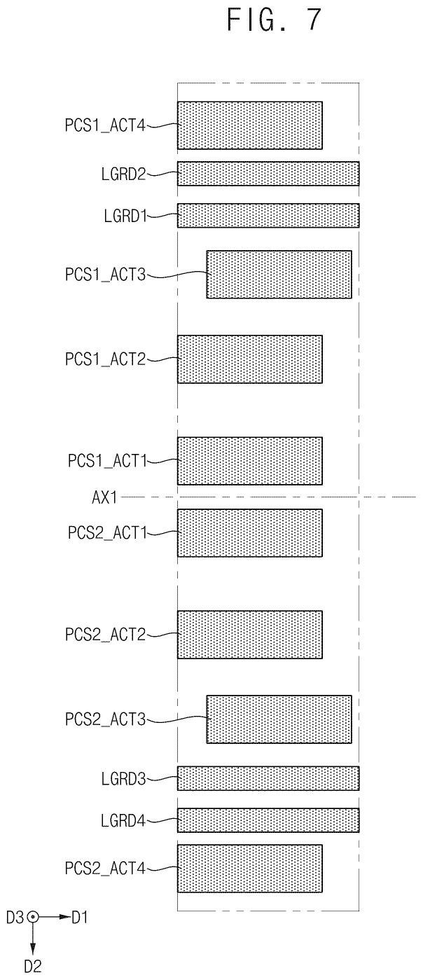

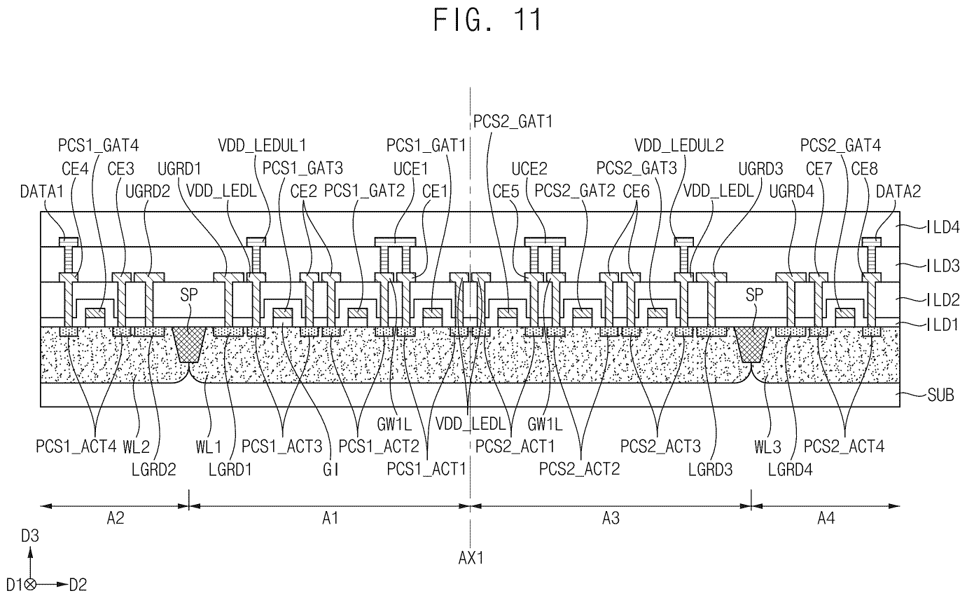

FIG. 4 is a plan view illustrating a pixel circuit structure and a guard trace included in the display device of FIG. 2. FIG. 5 is a plan view illustrating a first pixel circuit structure, a second pixel circuit structure, and a guard trace illustrated in FIG. 4. FIG. 6 is a layout diagram illustrating the first pixel circuit structure, the second pixel circuit structure, and the guard trace of FIG. 5. FIGS. 7, 8, 9, and 10 are layout diagrams illustrating the first pixel circuit structure, the second pixel circuit structure, and the guard trace of FIG. 6. FIG. 11 is a cross-sectional view illustrating the first pixel circuit structure, the second pixel circuit structure, and the guard trace of FIG. 5.

Referring to FIG. 4, the display device DD1 may include a plurality of pixel circuit structures and a plurality of guard traces.

For example, the display device DD1 may include a first pixel circuit structure PCS1, a second pixel circuit structure PCS2, a third pixel circuit structure PCS3, and a fourth pixel circuit structure PCS4. The pixel circuit structures may be arranged in a matrix shape along the first direction D1 and the second direction D2.

For example, the display device DD1 may include a first guard trace GDR1, a second guard trace GDR2, a third guard trace GDR3, a fourth guard trace GDR4, a fifth guard trace GDR5, a sixth guard trace GDR6, a seventh guard trace GDR7, and an eighth guard trace GDR8. Each of the guard traces may extend along the first direction D1 and be arranged side by side in the second direction D2. The guard trace may be disposed to cross a pixel circuit structure in a plan view and be a conductor to prevent a leakage current or electromagnetic interference from crossing the guard trace.

The second pixel circuit structure PCS2 may be adjacent to the first pixel circuit structure PCS1 in the second direction D2, the third pixel circuit structure PCS3 may be adjacent to the second pixel circuit structure PCS2 in the second direction D2, and the fourth pixel circuit structure PCS4 may be adjacent to the third pixel circuit structure PCS3 in the second direction D2.

In an embodiment, the second pixel circuit structure PCS2 may be symmetrical with the first pixel circuit structure PCS1. For example, the second pixel circuit structure PCS2 may be plane-symmetrical with the first pixel circuit structure PCS1 with respect to a first symmetry plane AX1 defined by the first direction D1 and the third direction D3 and located therebetween.

In an embodiment, the third pixel circuit structure PCS3 may be symmetrical with the second pixel circuit structure PCS2. For example, the third pixel circuit structure PCS3 may be plane-symmetrical with the second pixel circuit structure PCS2 with respect to a second symmetry plane AX2 defined by the first direction D1 and the third direction D3 and located therebetween.

In an embodiment, the fourth pixel circuit structure PCS4 may be symmetrical with the third pixel circuit structure PCS3. For example, the fourth pixel circuit structure PCS4 may be plane-symmetrical with the third pixel circuit structure PCS3 with respect to a third symmetry plane AX3 defined by the first direction D1 and the third direction D3 and located therebetween.

However, the present invention is not limited thereto. In another embodiment, the second pixel circuit structure may be adjacent to the first pixel circuit structure in the first direction D1 and may be symmetrical with respect to a symmetry plane parallel to the second direction D2 and the third direction D3. Accordingly, each of the guard traces may extend in the second direction D2 and be arranged side by side in the first direction D1.

Referring to FIG. 5, the first pixel circuit structure PCS1 may include a 1-1 transistor PCS1_T1, a 1-2 transistor PCS1_T2, a 1-3 transistor PCS1_T3, and a 1-4 transistor PCS1_T4. In an embodiment, the 1-1 transistor PCS1_T1, the 1-2 transistor PCS1_T2, and the 1-3 transistor PCS1_T3 may correspond to the first to third transistors T1, T2, and T3 described with reference to FIG. 3, respectively. The 1-4 transistor PCS1_T4 may correspond to the fourth transistor T4 described with reference to FIG. 3.

The first pixel circuit structure PCS1 may be divided into the first area A1 and the second area A2 adjacent to the first area A1. The 1-1 transistor PCS1_T1, the 1-2 transistor PCS1_T2, and the 1-3 transistor PCS1_T3 may be disposed in the first area A1. The 1-4 transistor PCS1_T4 may be disposed in the second area A2.

The first guard trace GDR1 may be disposed in the first area A1 and adjacent to the second area A2 and may be electrically connected to the first area A1 (e.g., first well WL1 in FIG. 11). Accordingly, the first high power voltage VDD_LED may be transmitted to the back gate terminal of the 1-1 transistor PCS1_T1, the back gate terminal of the 1-2 transistor PCS1_T2, the back gate terminal of the 1-3 transistor PCS1_T3, and the first guard trace GDR1.

The second guard trace GDR2 may be disposed in the second area A2 and adjacent to the first area A1 and may be electrically connected to the second area A2 (e.g., second well WL2 in FIG. 11). Accordingly, the second high power voltage VDD may be transmitted to the back gate terminal of the 1-4 transistor PCS1_T4 and the second guard trace GDR2. While the first guard trace GDR1 and the second guard trace GDR2 are disposed in the first area A1 and the second area A2, respectively, they are not parts of the first pixel circuit structure PCS1.

The second pixel circuit structure PCS2 may include a 2-1 transistor PCS2_T1, a 2-2 transistor PCS2_T2, a 2-3 transistor PCS2_T3, and a 1-4 transistor PCS2_T4. In an embodiment, the 2-1 transistor PCS2_T1, the 2-2 transistor PCS2_T2, and the 2-3 transistor PCS2_T3 may correspond to the first to third transistors T1, T2, and T3 described with reference to FIG. 3, respectively. The 2-4 transistor PCS2_T4 may correspond to the fourth transistor T4 described with reference to FIG. 3.

The second pixel circuit structure PCS2 may be divided into a third area A3 and a fourth area A4 adjacent to the third area A3. The 2-1 transistor PCS2_T1, the 2-2 transistor PCS2_T2, and the 2-3 transistor PCS2_T3 may be disposed in the third area A3. The 2-4 transistor PCS2_T4 may be disposed in the fourth area A4.

The third guard trace GDR3 may be disposed in the third area A3 and adjacent to the fourth area A4 and may be electrically connected to the third area A3 (e.g., first well WL1 in FIG. 11). Accordingly, the first high power voltage VDD_LED may be transmitted to the back gate terminal of the 2-1 transistor PCS2_T1, the back gate terminal of the 2-2 transistor PCS2_T2, the back gate terminal of the 2-3 transistor PCS2_T3, and the third guard trace GDR3.

The fourth guard trace GDR4 may be disposed in the fourth area A4 and adjacent to the third area A3 and may be electrically connected to the second area A4 (e.g., third well WL3 in FIG. 11). Accordingly, the second high power voltage VDD may be transmitted to the back gate terminal of the 2-4 transistor PCS2_T4 and the fourth guard trace GDR4. While the third guard trace GDR3 and the fourth guard trace GDR4 are disposed in the third area A3 and the fourth area A4, respectively, they are not parts of the second pixel circuit structure PCS2.

In an embodiment, the 1-1 transistor PCS1_T1 may be plane-symmetrical with the 2-1 transistor PCS2_T1 with respect to the first symmetry plane AX1. The 1-2 transistor PCS1_T2 may be plane-symmetrical with the 2-2 transistor PCS2_T2 with respect to the first symmetry plane AX1. The 1-3 transistor PCS1_T3 may be plane-symmetrical with the 2-3 transistor PCS2_T3 with respect to the first symmetry plane AX1. The 1-4 transistor PCS1_T4 may be plane-symmetrical with the 2-4 transistor PCS2_T4 with respect to the first symmetry plane AX1.

In an embodiment, the first guard trace GDR1 and the third guard trace GDR3 may face each other, and no guard trace may be disposed between the first guard trace GDR1 and the third guard trace GDR3. In other words, the first area A1 and the third area A3 may be connected to each other, and no guard trace extending in the first direction D1 may be disposed at a border between the first area A1 and the third area A3. Accordingly, the distance in the second direction D2 between the first pixel circuit structure PCS1 and the second pixel circuit structure PCS2 may be shortened, and the resolution of the display device DD1 may be effectively improved.

Referring to FIG. 6, a plurality of active patterns, a plurality of gate electrodes, and a plurality of lines may be formed, and the first and second pixel circuit structures PCS1 and PCS2 may be formed through the plurality of active patterns, the plurality of gate electrodes, and the plurality of lines. This will be described in detail below.

Referring to FIGS. 7 and 11, as described above, the substrate SUB may be a semiconductor substrate. By doping the substrate SUB with impurities, a first well WL1, a second well WL2, and a third well WL3 may be formed.

In an embodiment, as illustrated in FIG. 3, when a PMOS transistor is formed, an impurity such as phosphorus that imparts n-type conductivity to the substrate SUB may be doped to form the first well WL1, the second well WL2, and the third well WL3. The first well WL1 may be formed in the first area A1 and the third area A3, the second well WL2 may be formed in the second area A2, and the third well WL3 may be formed in the fourth area A4. The first well WL1, the second well WL2, and the third well WL3 may be separated by a partition SP.

The active patterns may be disposed on the substrate SUB. For example, the active patterns may include a 1-1 active pattern PCS1_ACT1, a 1-2 active pattern PCS1_ACT2, a 1-3 active pattern PCS1_ACT3, a 1-4 active pattern PCS1_ACT4, a 2-1 active pattern PCS2_ACT1, a 2-2 active pattern PCS2_ACT2, a 2-3 active pattern PCS2_ACT3, and a 2-4 active pattern PCS2_ACT4.

In an embodiment, when a PMOS transistor is formed, as illustrated in FIG. 3, the active patterns may include an impurity, such as boron, that imparts p-type conductivity.

In an embodiment, lower guard traces may be formed together with the active patterns. For example, the lower guard traces may include a first lower guard trace LGRD1, a second lower guard trace LGRD2, a third lower guard trace LGRD3, and a fourth lower guard trace LGRD4. The first to fourth lower guard traces LGRD1, LGRD2, LGRD3, and LGRD4 may be disposed in the same layer as the active patterns and may include the same material.

In an embodiment, each of the first to fourth lower guard traces LGRD1, LGRD2, LGRD3, and LGRD4 may extend in the first direction D1 and be arranged side by side in the second direction D2. The first lower guard trace LGRD1 may be disposed in the first area A1 and adjacent to the second area A2, the second lower guard trace LGRD2 may be disposed in the second area A2 and adjacent to the first area A1, the third lower guard trace LGRD3 may be disposed in the third area A3 and adjacent to the fourth area A4, and the fourth lower guard trace LGRD4 may be disposed in the fourth area A4 and adjacent to the third area A3.

A gate insulating layer GI may be disposed on the substrate SUB. The gate insulating layer GI may include an inorganic insulating material and/or an organic insulating material.

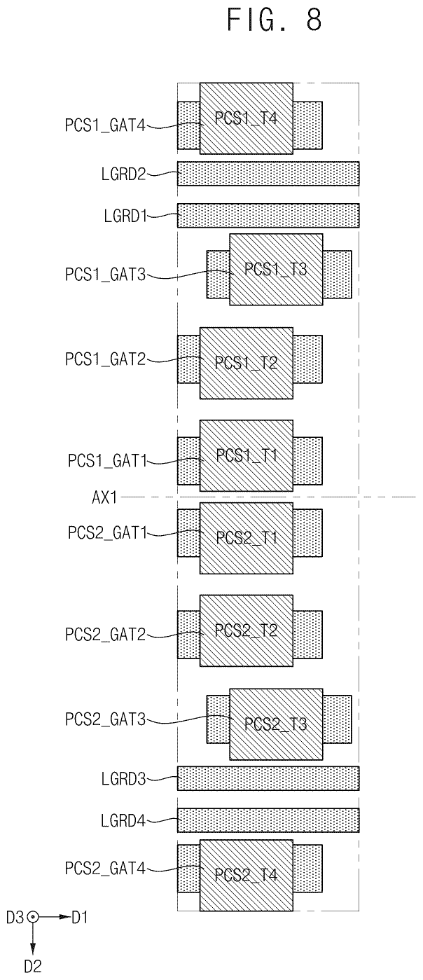

Referring to FIGS. 8 and 11, gate electrodes may be disposed on the gate insulating layer GI. For example, the gate electrodes may include a 1-1 gate electrode PCS1_GAT1, a 1-2 gate electrode PCS1_GAT2, a 1-3 gate electrode PCS1_GAT3, a 1-4 gate electrode PCS1_GAT4, a 2-1 gate electrode PCS2_GAT1, a 2-2 gate electrode PCS2_GAT2, a 2-3 gate electrode PCS2_GAT3, and a 2-4 gate electrode PCS2_GAT4.

The 1-1 gate electrode PCS1_GAT1 may overlap the 1-1 active pattern PCS1_ACT1. The 1-1 active pattern PCS1_ACT1 and the 1-1 gate electrode PCS1_GAT1 may form the 1-1 transistor PCS1_T1.

The 1-2 gate electrode PCS1_GAT2 may overlap the 1-2 active pattern PCS1_ACT2. The 1-2 active pattern PCS1_ACT2 and the 1-2 gate electrode PCS1_GAT2 may form the 1-2 transistor PCS1_T2.

The 1-3 gate electrode PCS1_GAT3 may overlap the 1-3 active pattern PCS1_ACT3. The 1-3 active pattern PCS1_ACT3 and the 1-3 gate electrode PCS1_GAT3 may form the 1-3 transistor PCS1_T3.

The 1-4 gate electrode PCS1_GAT4 may overlap the 1-4 active pattern PCS1_ACT4. The 1-4 active pattern PCS1_ACT4 and the 1-4 gate electrode PCS1_GAT4 may form the 1-4 transistor PCS1_T4.

The 2-1 gate electrode PCS2_GAT1 may overlap the 2-1 active pattern PCS2_ACT1. The 2-1 active pattern PCS2_ACT1 and the 2-1 gate electrode PCS2_GAT1 may form the 2-1 transistor PCS2_T1.

The 2-2 gate electrode PCS2_GAT2 may overlap the 2-2 active pattern PCS2_ACT2. The 2-2 active pattern PCS2_ACT2 and the 2-2 gate electrode PCS2_GAT2 may form the 2-2 transistor PCS2_T2.

The 2-3 gate electrode PCS2_GAT3 may overlap the 2-3 active pattern PCS2_ACT3. The 2-3 active pattern PCS2_ACT3 and the 2-3 gate electrode PCS2_GAT3 may form the 2-3 transistor PCS2_T3.

The 2-4 gate electrode PCS2_GAT4 may overlap the 2-4 active pattern PCS2_ACT4. The 2-4 active pattern PCS2_ACT4 and the 2-4 gate electrode PCS2_GAT4 may form the 2-4 transistor PCS2_T4.

In an embodiment, the gate electrodes may include a metal, an alloy, a conductive metal oxide, and the like. For example, the gate electrodes may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like.

A first insulating layer ILD1 and a second insulating layer ILD2 may cover the gate electrodes and may be disposed on the gate electrodes. In an embodiment, each of the first insulating layer ILD1 and the second insulating layer ILD2 may include an inorganic insulating material and/or an organic insulating material.

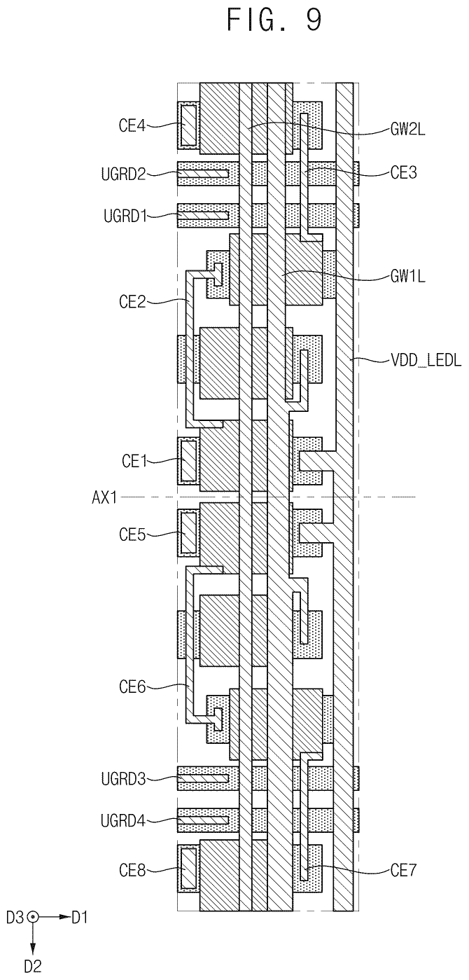

Referring to FIGS. 9 and 11, a first high power supply voltage line VDD_LEDL, a first gate signal line GW1L, a second gate signal line GW2L, and connecting electrodes may be disposed on the second insulating layer ILD2. The connecting electrodes may include first to eighth connecting electrodes CE1, CE2, CE3, CE4, CE5, CE6, CE7, and CE8.

The first high power voltage line VDD_LEDL may extend in the second direction D2. In an embodiment, the first high power voltage line VDD_LEDL may have a shape that is symmetrical with respect to the first symmetry plane AX1. The first high power voltage line VDD_LEDL may be electrically connected to the 1-1 active pattern PCS1_ACT1, the 1-3 active pattern PCS1_ACT3, the 2-1 active pattern PCS2_ACT1, and the 2-3 active pattern PCS2_ACT3. The first high power voltage line VDD_LEDL may transmit the first high power voltage VDD_LED.

The first gate signal line GW1L may extend in the second direction D2. In an embodiment, the first gate signal line GW1L may have a shape that is symmetrical with respect to the first symmetry plane AX1. The first gate signal line GW1L may be electrically connected to the 1-4 gate electrode PCS1_GAT4 and the 2-4 gate electrode PCS2_GAT4. The first gate signal line GW1L may transmit the first gate signal GW1.

The second gate signal line GW2L may extend in the second direction D2. In an embodiment, the second gate signal line GW2L may have a shape that is symmetrical with respect to the first symmetry plane AX1. The second gate signal line GW2L may be electrically connected to the 1-2 gate electrode PCS1_GAT2 and the 2-2 gate electrode PCS2_GAT2. The second gate signal line GW2L may transmit the second gate signal GW2.

The first connecting electrode CE1 may be electrically connected to the 1-1 active pattern PCS1_ACT1.

The second connecting electrode CE2 may be electrically connected to the 1-1 gate electrode PCS1_GAT1, the 1-2 active pattern PCS1_ACT2, and the 1-3 active pattern PCS1_ACT3.

The third connecting electrode CE3 may be electrically connected to the 1-3 gate electrode PCS1_GAT3 and the 1-4 active pattern PCS1_ACT4.

The fourth connecting electrode CE4 may be electrically connected to the 1-4 active pattern PCS1_ACT4.

The fifth connecting electrode CE5 may be electrically connected to the 2-1 active pattern PCS2_ACT1. In an embodiment, the fifth connecting electrode CE5 may be symmetrical with the first connecting electrode CE1 with respect to the first symmetry plane AX1.

The sixth connecting electrode CE6 may be electrically connected to the 2-1 gate electrode PCS2_GAT1, the 2-2 active pattern PCS2_ACT2, and the 2-3 active pattern PCS2_ACT3. In an embodiment, the sixth connecting electrode CE6 may be plane-symmetrical with the second connecting electrode CE2 with respect to the first symmetry plane AX1.

The seventh connecting electrode CE7 may be electrically connected to the 2-3 gate electrode PCS2_GAT3 and the 2-4 active pattern PCS2_ACT4. In an embodiment, the seventh connecting electrode CE7 may be plane-symmetrical with the third connecting electrode CE3 with respect to the first symmetry plane AX1.

The eighth connecting electrode CE8 may be electrically connected to the 2-4 active pattern PCS2_ACT4. In an embodiment, the eighth connecting electrode CE8 may be plane-symmetrical with the fourth connecting electrode CE4 with respect to the first symmetry plane AX1.

In an embodiment, the first high power supply voltage line VDD_LEDL, the first gate signal line GW1L, the second gate signal line GW2L, and the connecting electrodes may include a metal, an alloy, a conductive metal oxide, or the like. For example, the first high power supply voltage line VDD_LEDL, the first gate signal line GW1L, the second gate signal line GW2L, and the connecting electrodes may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like.

In an embodiment, the upper guard traces may be formed together with the first high power voltage line VDD_LEDL, the first gate signal line GW1L, the second gate signal line GW2L, and the connecting electrodes. For example, the upper guard traces may include a first upper guard trace UGRD1, a second upper guard trace UGRD2, a third upper guard trace UGRD3, and a fourth upper guard trace UGRD4. The first to fourth upper guard traces UGRD1, UGRD2, UGRD3, and UGRD4 may be disposed in the same layer as the first high power voltage line VDD_LEDL, the first gate signal line GW1L, the second gate signal line GW2L, and the connecting electrodes, and may include the same material.

The first upper guard trace UGRD1 may be disposed in an island shape and may contact the first lower guard trace LGRD1 through a contact hole. The first lower guard trace LGRD1 and the first upper guard trace UGRD1 may constitute the first guard trace GRD1 and may be electrically connected to the first well WL1 formed in the first area A1 and the third area A3.

The second upper guard trace UGRD2 may be disposed in an island shape and may contact the second lower guard trace LGRD2 through a contact hole. The second lower guard trace LGRD2 and the second upper guard trace UGRD2 may constitute the second guard trace GRD2 and may be electrically connected to the second well WL2 formed in the second area A2.

The third upper guard trace UGRD3 may be disposed in an island shape and may contact the third lower guard trace LGRD3 through a contact hole. The third lower guard trace LGRD3 and the third upper guard trace UGRD3 may constitute the third guard trace GRD3 and may be electrically connected to the first well WL1 formed in the first area A1 and the third area A3.

In an embodiment, the third upper guard trace UGRD3 may be plane-symmetrical with the first upper guard trace UGRD1 with respect to the first symmetry plane AX1.

The fourth upper guard trace UGRD4 may be disposed in an island shape and may contact the fourth lower guard trace LGRD4 through a contact hole. The fourth lower guard trace LGRD4 and the fourth upper guard trace UGRD4 may constitute the fourth guard trace GRD4 and may be electrically connected to the third well WL3 formed in the fourth area A4.

In an embodiment, the fourth upper guard trace UGRD4 may be plane-symmetrical with the second upper guard trace UGRD2 with respect to the first symmetry plane AX1.

A third insulating layer IL3 may be disposed on the second insulating layer IL2 and may cover the first high power voltage line VDD_LEDL, the first gate signal line GW1L, the second gate signal line GW2L, the connecting electrodes, and the upper guard traces. The third insulating layer IL3 may include an inorganic insulating material and/or an organic insulating material.

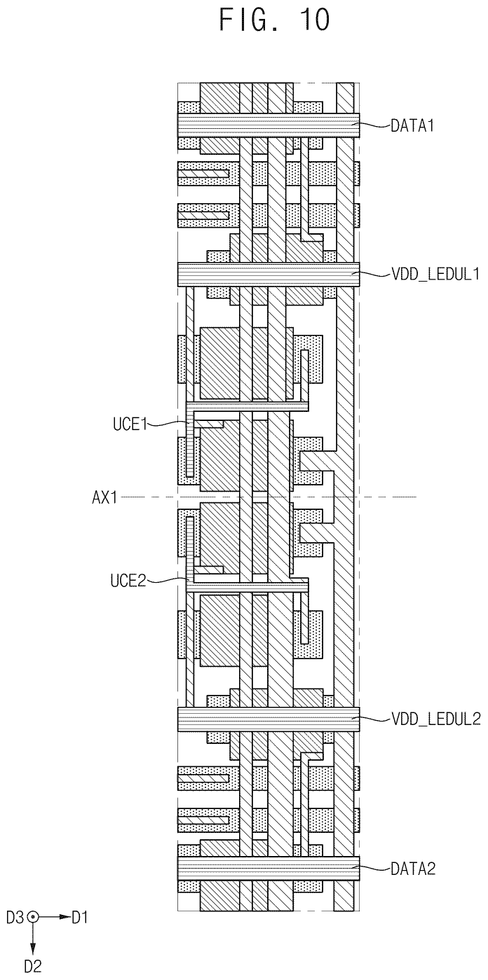

Referring to FIGS. 10 and 11, a first data voltage line DATA1, a second data voltage line DATA2, a first upper high power voltage line VDD_LEDUL1, a second upper high power voltage line VDD_LEDUL2, and upper connecting electrodes may be disposed. The upper connecting electrodes may include a first upper connecting electrode UCE1 and a second upper connecting electrode UCE2.

The first data voltage line DATA1 may extend in the first direction D1. The first data voltage line DATA1 may be electrically connected to the fourth connecting electrode CE4 and may transmit the data voltage DATA.

The second data voltage line DATA2 may extend in the first direction D1. The second data voltage line DATA2 may be electrically connected to the eighth connecting electrode CE8 and may transmit the data voltage DATA.

In an embodiment, the second data voltage line DATA2 may be plane-symmetrical with the first data voltage line DATA1 with respect to the first symmetry plane AX1.

The first upper high power voltage line VDD_LEDUL1 may extend in the first direction D1. The first upper high power voltage line VDD_LEDUL1 may be electrically connected to the first high power voltage line VDD_LEDL and may transmit the first high power voltage VDD_LED.

The second upper high power voltage line VDD_LEDUL2 may extend in the first direction D1. The second upper high power voltage line VDD_LEDUL2 may be electrically connected to the first high power voltage line VDD_LEDL and may transmit the first high power voltage VDD_LED.

In an embodiment, the second upper high power supply voltage line VDD_LEDUL2 may be plane-symmetrical with the first upper high power supply voltage line VDD_LEDUL1 with respect to the first symmetry plane AX1.

The first upper connecting electrode UCE1 may be electrically connected to the first connecting electrode CE1 and the first gate signal line GW1L.

The second upper connecting electrode UCE2 may be electrically connected to the fifth connecting electrode CE5 and the first gate signal line GW1L.

In an embodiment, the second upper connecting electrode UCE2 may be plane-symmetrical with the first upper connecting electrode UCE1 with respect to the first symmetry plane AX1.

A display device DD1 according to an embodiment of the present invention may include a first pixel circuit structure PCS1 and a second pixel circuit structure PCS2. The second pixel circuit structure PCS2 may be adjacent to the first pixel circuit structure PCS1 in the second direction D2. In an embodiment, the second pixel circuit structure PCS2 may be plane-symmetrical with the first pixel circuit structure PCS1 with respect to a first symmetry plane AX1 parallel to the first direction D1 and the third direction D3.

Since the second pixel circuit structure PCS2 is plane-symmetrical with the first pixel circuit structure PCS1 with respect to the first symmetry plane AX1, the first area A1 of the first pixel circuit structure PCS1 and the third area A3 of the second pixel circuit structure PCS2 may be connected to each other. Accordingly, the first well WL1 may be formed continuously in the first and third areas A1 and A3. In other words, the first well WL1 may not be separated. Accordingly, a guard trace extending in the first direction D1 may not be disposed at a border between the first and second pixel circuit structures PCS1 and PCS2, and the distance in the second direction D2 between the first pixel circuit structure PCS1 and the second pixel circuit structure PCS2 may be shortened. Accordingly, the resolution of the display device DD1 can be effectively improved.

However, the present invention is not limited thereto. In another embodiment, the second pixel circuit structure may be adjacent to the first pixel circuit structure in the first direction D1 and may be plane-symmetrical with respect to a symmetry plane parallel to the second direction D2 and the third direction D3. Accordingly, each of the guard traces may extend in the second direction D2 and be disposed in parallel in the first direction D1. Accordingly, the distance between the first pixel circuit structure and the second pixel circuit structure in the first direction D1 may be shortened.

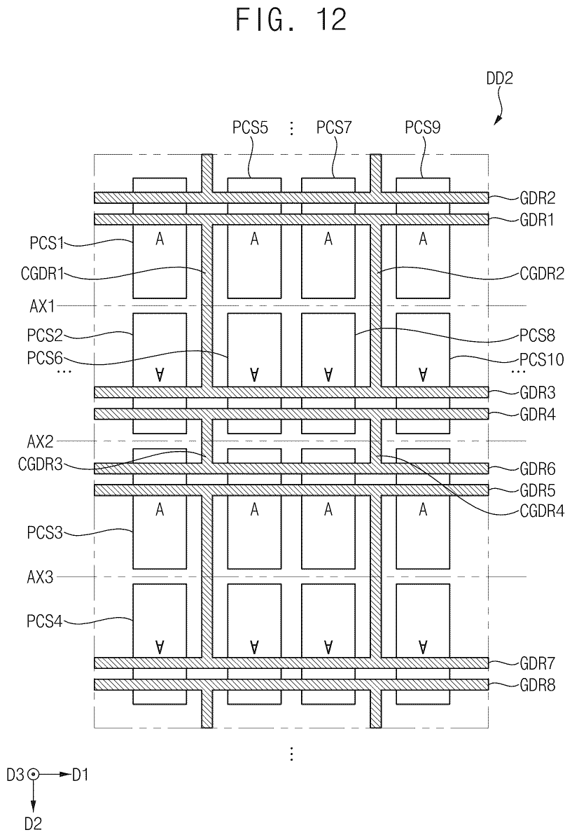

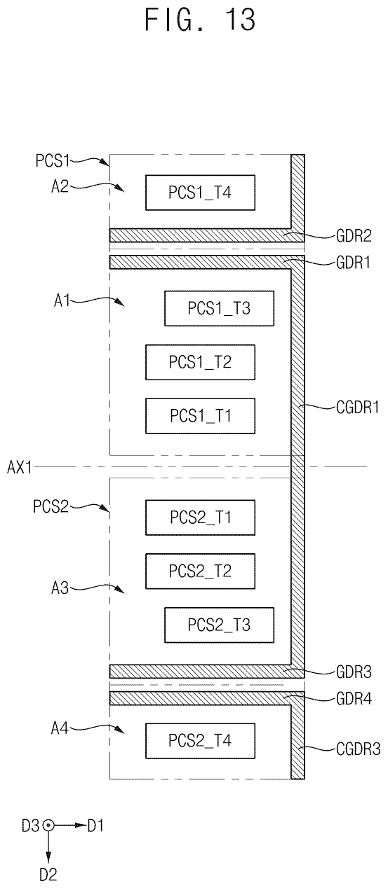

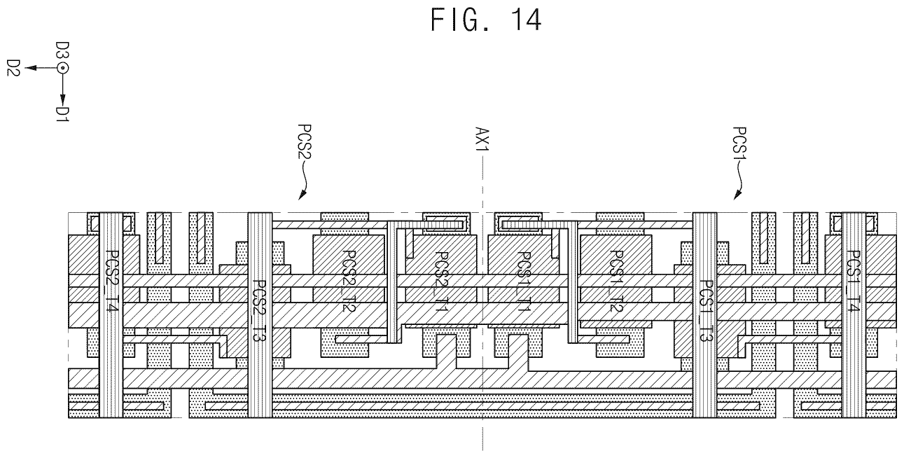

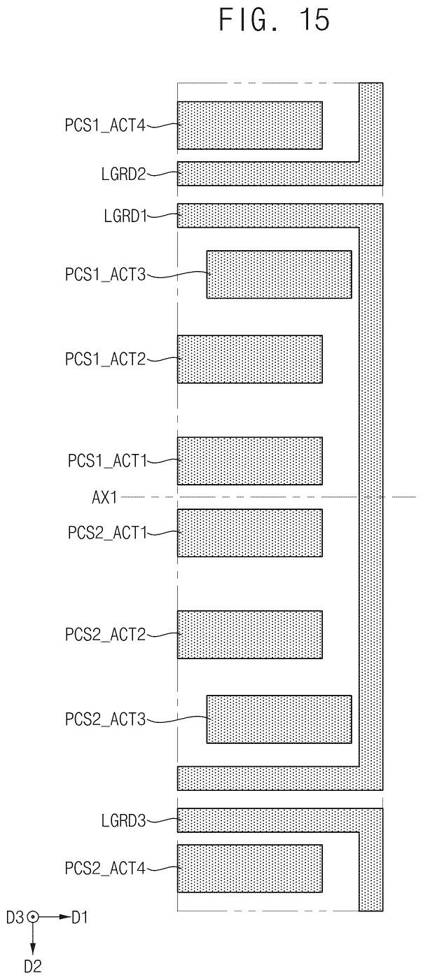

FIG. 12 is a plan view illustrating a pixel circuit structure and a guard trace included in a display device according to another embodiment of the present invention. FIG. 13 is a plan view illustrating a first pixel circuit structure, a second pixel circuit structure, and a guard trace illustrated in FIG. 12. FIG. 14 is a layout diagram illustrating the first pixel circuit structure, the second pixel circuit structure, and the guard trace illustrated in FIG. 13. FIGS. 15, 16, 17, and 18 are layout diagrams illustrating the first pixel circuit structure, the second pixel circuit structure, and the guard trace of FIG. 14.

Referring to FIG. 12, a display device DD2 according to another embodiment of the present invention may include a plurality of pixel circuit structures, a plurality of guard traces, and a plurality of connecting guard traces. However, the display device DD2 may be substantially the same as the display device DD1 described above, except for the connecting guard traces.

For example, the pixel circuit structures may include a first pixel circuit structure PCS1, a second pixel circuit structure PCS2, a third pixel circuit structure PCS3, a fourth pixel circuit structure PCS4, a fifth pixel circuit structure PCS5, a sixth pixel circuit structure PCS6, a seventh pixel circuit structure PCS7, an eighth pixel circuit structure PCS8, a ninth pixel circuit structure PCS9, and a tenth pixel circuit structure PCS10. The pixel circuit structures may be arranged in a matrix shape along the first direction D1 and the second direction D2.

For example, the guard traces may include a first guard trace GDR1, a second guard trace GDR2, a third guard trace GDR3, a fourth guard trace GDR4, a fifth guard trace GDR5, a sixth guard trace GDR6, a seventh guard trace GDR7, and an eighth guard trace GDR8. Each of the guard traces may extend along the first direction D1 and be arranged side by side in the second direction D2.

For example, the connecting guard traces may include a first connecting guard trace CGDR1, a second connecting guard trace CGDR2, a third connecting guard trace CGDR3, and a fourth connecting guard trace CGDR4. Each of the connecting guard traces may extend along the second direction D2 and be arranged side by side in the first direction D1.

In an embodiment, the fifth pixel circuit structure PCS5 may be adjacent to the first pixel circuit structure PCS1 in the first direction D1, and the sixth pixel circuit structure PCS6 may be adjacent to the fifth pixel circuit structure PCS5 in the second direction D2.

In an embodiment, the seventh pixel circuit structure PCS7 may be adjacent to the fifth pixel circuit structure PCS5 in the first direction D1, and the eighth pixel circuit structure PCS8 may be adjacent to the seventh pixel circuit structure PCS7 in the second direction D2.

In an embodiment, the ninth pixel circuit structure PCS9 may be adjacent to the seventh pixel circuit structure PCS7 in the first direction D1, and the tenth pixel circuit structure PCS10 may be adjacent to the ninth pixel circuit structure PCS9 in the second direction D2.

In an embodiment, the connecting guard traces may be disposed between the pixel circuit structures. For example, as shown in FIG. 12, the first connecting guard trace CGDR1 may be disposed between the first pixel circuit structure PCS1 and the fifth pixel circuit structure PCS5, the second connecting guard trace CGDR2 may be disposed between the seventh pixel circuit structure PCS7 and the ninth pixel circuit structure PCS9, the third connecting guard trace CGDR3 may be disposed between the second pixel circuit structure PCS2 and the sixth pixel circuit structure PCS6, and the fourth connecting guard trace CGDR4 may be disposed between the eighth pixel circuit structure PCS8 and the tenth pixel circuit structure PCS10.

In an embodiment, as shown in FIG. 12, each of the connecting guard traces may be disposed for every two pixel columns. However, the present invention is not limited thereto. In another embodiment, each of the connecting guard traces may be disposed for every one pixel column. In still another embodiment, each of the connecting guard traces may be disposed for every three or more pixel columns.

In an embodiment, the first connecting guard trace CGDR1 may be connected to the first guard trace GDR1 and the third guard trace GDR3. In addition, the first connecting guard trace CGDR1 may be disconnected from the second guard trace GDR2 and the fourth guard trace GDR4. Accordingly, the first connecting guard trace CGDR1 may be electrically connected to the first area A1 together with the first guard trace GDR1 and the third guard trace GDR3.

In an embodiment, the second connecting guard trace CGDR2 may be connected to the first guard trace GDR1 and the third guard trace GDR3. In addition, the second connecting guard trace CGDR2 may be disconnected from the second guard trace GDR2 and the fourth guard trace GDR4. Accordingly, the second connecting guard trace CGDR2 may be electrically connected to the first area A1 together with the first guard trace GDR1 and the third guard trace GDR3.

In an embodiment, the third connecting guard trace CGDR3 may be connected to the fourth guard trace GDR4 and the sixth guard trace GDR6. In addition, the third connecting guard trace CGDR3 may be disconnected from the first guard trace GDR1 and the third guard trace GDR3. Accordingly, the third connecting guard trace CGDR3 may be electrically connected to the fourth area A4 together with the fourth guard trace GDR4.

In an embodiment, the fourth connecting guard trace CGDR4 may be connected to the fourth guard trace GDR4 and the sixth guard trace GDR6. In addition, the fourth connecting guard trace CGDR4 may be disconnected from the first guard trace GDR1 and the third guard trace GDR3. Accordingly, the fourth connecting guard trace CGDR4 may be electrically connected to the fourth area A4 together with the fourth guard trace GDR4.

In addition, since each of the above connecting guard traces is connected to the guard traces, a voltage drop (IR drop) defect that may occur in the guard traces can be prevented. For example, since the first connecting guard trace CGDR1 is connected to the first and third guard traces GDR1 and GDR3, a voltage drop defect that may occur in the first and third guard traces GDR1 and GDR3 can be prevented.

Referring to FIG. 13, the first pixel circuit structure PCS1 may include a 1-1 transistor PCS1_T1, a 1-2 transistor PCS1_T2, a 1-3 transistor PCS1_T3, and a 1-4 transistor PCS1_T4. In an embodiment, the 1-1 transistor PCS1_T1, the 1-2 transistor PCS1_T2, and the 1-3 transistor PCS1_T3 may correspond to the first to third transistors T1, T2, and T3 described with reference to FIG. 3, respectively. The 1-4 transistor PCS1_T4 may correspond to the fourth transistor T4 described with reference to FIG. 3.

The first pixel circuit structure PCS1 may be divided into the first area A1 and the second area A2 adjacent to the first area A1. The 1-1 transistor PCS1_T1, the 1-2 transistor PCS1_T2, and the 1-3 transistor PCS1_T3 may be disposed in the first area A1. The 1-4 transistor PCS1_T4 may be disposed in the second area A2.

The first guard trace GDR1 may be disposed in the first area A1 and adjacent to the second area A2 and may be electrically connected to the first area A1 (e.g., first well WL1 in FIG. 11). Accordingly, the first high power voltage VDD_LED may be transmitted to the back gate terminal of the 1-1 transistor PCS1_T1, the back gate terminal of the 1-2 transistor PCS1_T2, the back gate terminal of the 1-3 transistor PCS1_T3, and the first guard trace GDR1.

The second guard trace GDR2 may be disposed in the second area A2 and adjacent to the first area A1 and may be electrically connected to the second area A2 (e.g., second well WL2 in FIG. 11). Accordingly, the second high power voltage VDD may be transmitted to the back gate terminal of the 1-4 transistor PCS1_T4 and the second guard trace GDR2. While the first guard trace GDR1 and the second guard trace GDR2 are disposed in the first area A1 and the second area A2, respectively, they are not parts of the first pixel circuit structure PCS1.

The second pixel circuit structure PCS2 may include a 2-1 transistor PCS2_T1, a 2-2 transistor PCS2_T2, a 2-3 transistor PCS2_T3, and a 2-4 transistor PCS2_T4. In an embodiment, the 2-1 transistor PCS2_T1, the 2-2 transistor PCS2_T2, and the 2-3 transistor PCS2_T3 may correspond to the first to third transistors T1, T2, and T3 described with reference to FIG. 3, respectively. The 2-4 transistor PCS2_T4 may correspond to the fourth transistor T4 described with reference to FIG. 3.

The second pixel circuit structure PCS2 may be divided into a third area A3 and a fourth area A4 adjacent to the third area A3. The 2-1 transistor PCS2_T1, the 2-2 transistor PCS2_T2, and the 2-3 transistor PCS2_T3 may be disposed in the third area A3. The 2-4 transistor PCS2_T4 may be disposed in the fourth area A4.

The third guard trace GDR3 may be disposed in the third area A3 and adjacent to the fourth area A4 and may be electrically connected to the third area A3 (e.g., first well WL1 in FIG. 11). Accordingly, the first high power voltage VDD_LED may be transmitted to the back gate terminal of the 2-1 transistor PCS2_T1, the back gate terminal of the 2-2 transistor PCS2_T2, the back gate terminal of the 2-3 transistor PCS2_T3, and the third guard trace GDR3.

The fourth guard trace GDR4 may be disposed in the fourth area A4 and adjacent to the third area A3 and may be electrically connected to the second area A4 (e.g., third well WL3 in FIG. 11). Accordingly, the second high power voltage VDD may be transmitted to the back gate terminal of the 2-4 transistor PCS2_T4 and the fourth guard trace GDR4. While the third guard trace GDR3 and the fourth guard trace GDR4 are disposed in the third area A3 and the fourth area A4, respectively, they are not parts of the second pixel circuit structure PCS2.

In an embodiment, the 1-1 transistor PCS1_T1 may be plane-symmetrical with the 2-1 transistor PCS2_T1 with respect to the first symmetry plane AX1. The 1-2 transistor PCS1_T2 may be plane-symmetrical with the 2-2 transistor PCS2_T2 with respect to the first symmetry plane AX1. The 1-3 transistor PCS1_T3 may be plane-symmetrical with the 2-3 transistor PCS2_T3 with respect to the first symmetry plane AX1. The 1-4 transistor PCS1_T4 may be plane-symmetrical with the 2-4 transistor PCS2_T4 with respect to the first symmetry plane AX1.

In an embodiment, the first connecting guard trace CGDR1 may extend in the second direction D2 and be disposed in the first area A1 and the third area A3. The first connecting guard trace CGDR1 may be connected to the first guard trace GDR1 and the third guard trace GDR3, and thus may be electrically connected to the first area A1 and the third area A3. Accordingly, the first high power voltage VDD_LED may be transmitted to the first connecting guard trace CGDR1.

In an embodiment, the third connecting guard trace CGDR3 may extend in the second direction D2 and be disposed in the fourth area A4. The third connecting guard trace CGDR3 may be connected to the fourth guard trace GDR4, and thus may be electrically connected to the fourth area A4. Accordingly, the second high power voltage VDD may be transmitted to the third connecting guard trace CGDR3.

Referring to FIG. 14, a plurality of active patterns, a plurality of gate electrodes, and a plurality of lines may be formed, and the first and second pixel circuit structures PCS1 and PCS2 may be formed through the plurality of active patterns, the plurality of gate electrodes, and the plurality of lines. This will be described in detail below.

Referring to FIG. 15, active patterns may be disposed on the substrate SUB. For example, the active patterns may include a 1-1 active pattern PCS1_ACT1, a 1-2 active pattern PCS1_ACT2, a 1-3 active pattern PCS1_ACT3, a 1-4 active pattern PCS1_ACT4, a 2-1 active pattern PCS2_ACT1, a 2-2 active pattern PCS2_ACT2, a 2-3 active pattern PCS2_ACT3, and a 2-4 active pattern PCS2_ACT4.

However, the above active patterns may be substantially same as the active patterns described above with reference to FIG. 7.

In an embodiment, the lower guard traces may be formed together with the active patterns. For example, the lower guard traces may include a first lower guard trace LGRD1, a second lower guard trace LGRD2, and a third lower guard trace LGRD3. The first to third lower guard traces LGRD1, LGRD2, and LGRD3 may be disposed in the same layer as the active patterns and may include the same material.

In an embodiment, the first lower guard trace LGRD1 may extend in the first direction D1 and the second direction D2. The first lower guard trace LGRD1 extending in the first direction D1 in the first area A1 may constitute the first guard trace GDR1 shown in FIG. 13. The first lower guard trace LGRD1 extending in the first direction D1 in the third area A3 may constitute the third guard trace GDR3 shown in FIG. 13. The first lower guard trace LGDR1 extending in the second direction D2 in the first and third areas A1 and A3 may constitute the first connecting guard trace CGDR1 shown in FIG. 13.

In one embodiment, the second lower guard trace LGRD2 may extend in the first direction D1 and the second direction D2, and the third lower guard trace LGDR3 may extend in the first direction D1 and the second direction D2. The third lower guard trace LGDR3 extending in the first direction D1 may constitute the fourth guard trace GDR4 shown in FIG. 13. The third lower guard trace LGDR3 extending in the second direction D2 may constitute the third connecting guard trace CGDR3 shown in FIG. 13.

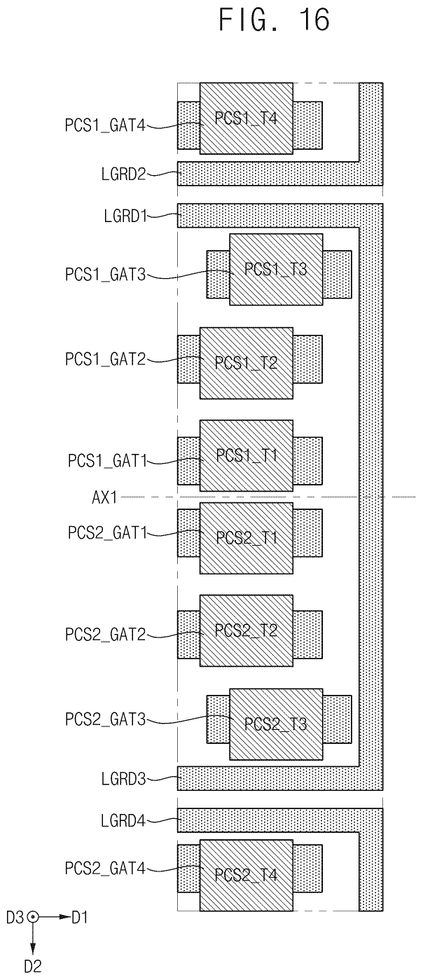

Referring to FIG. 16, gate electrodes may be disposed on the gate insulating layer GI. For example, the gate electrodes may include a 1-1 gate electrode PCS1_GAT1, a 1-2 gate electrode PCS1_GAT2, a 1-3 gate electrode PCS1_GAT3, a 1-4 gate electrode PCS1_GAT4, a 2-1 gate electrode PCS2_GAT1, a 2-2 gate electrode PCS2_GAT2, a 2-3 gate electrode PCS2_GAT3, and a 2-4 gate electrode PCS2_GAT4.

However, the gate electrodes may be substantially same as the gate electrodes described above with reference to FIG. 8.

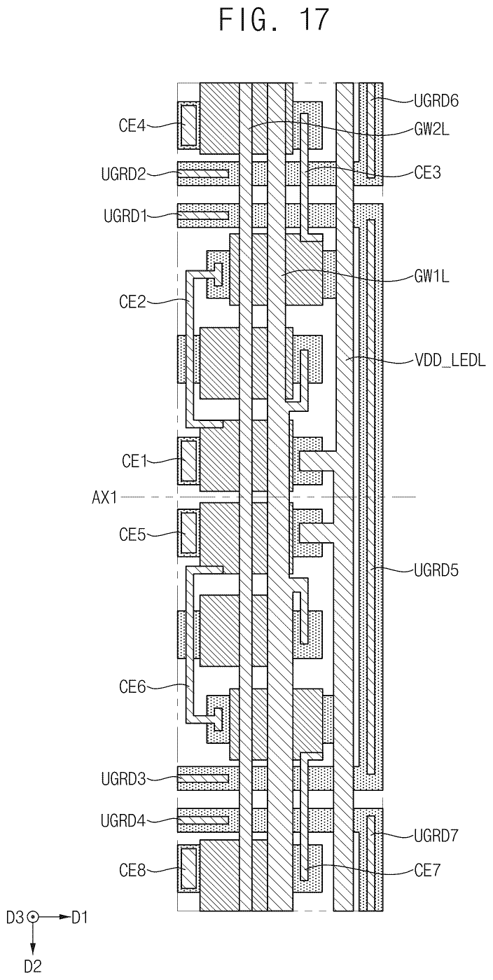

Referring to FIG. 17, a first high power supply voltage line VDD_LEDL, a first gate signal line GW1L, a second gate signal line GW2L, and connecting electrodes may be disposed on the second insulating layer ILD2. The connecting electrodes may include first to eighth connecting electrodes CE1, CE2, CE3, CE4, CE5, CE6, CE7, and CE8.

However, the first high power supply voltage line VDD_LEDL, the first gate signal line GW1L, the second gate signal line GW2L, and the connecting electrodes may be substantially the same as the first high power supply voltage line VDD_LEDL, the first gate signal line GW1L, the second gate signal line GW2L, and the connecting electrodes described above with reference to FIG. 9.

In an embodiment, upper guard traces may be formed together with the first high power voltage line VDD_LEDL, the first gate signal line GW1L, the second gate signal line GW2L, and the connecting electrodes. For example, the upper guard traces may include a first upper guard trace UGRD1, a second upper guard trace UGRD2, a third upper guard trace UGRD3, a fourth upper guard trace UGRD4, a fifth upper guard trace UGRD5, a sixth upper guard trace UGRD6, and a seventh upper guard trace UGRD7. The first to seventh upper guard traces UGRD1, UGRD2, UGRD3, UGRD4, UGRD5, UGRD6, and UGRD7 may be disposed in the same layer as the first high power voltage line VDD_LEDL, the first gate signal line GW1L, the second gate signal line GW2L, and the connecting electrodes, and may include the same material.

However, the first to fourth upper guard traces UGRD1, UGRD2, UGRD3, and UGRD4 may be substantially the same as the first to fourth upper guard traces UGRD1, UGRD2, UGRD3, and UGRD4 described with reference to FIG. 9.

The fifth upper guard trace UGRD5 may be disposed in an island shape extending in the second direction D2 and may contact the first lower guard trace LGRD1 through a contact hole. The first lower guard trace LGRD1 and the fifth upper guard trace UGRD5 may constitute the first connecting guard trace CGRD1 and may be electrically connected to the first well WL1 formed in the first and third areas A1 and A3.

The sixth upper guard trace UGRD6 may be disposed in an island shape extending in the second direction D2 and may contact the second lower guard trace LGRD2 through a contact hole.

The seventh upper guard trace UGRD7 may be disposed in an island shape extending in the second direction D2 and may contact the third lower guard trace LGRD3 through a contact hole. The seventh lower guard trace LGRD7 and the third upper guard trace UGRD3 may constitute the third connecting guard trace GRD3 and may be electrically connected to the third well WL3 formed in the fourth area A4.

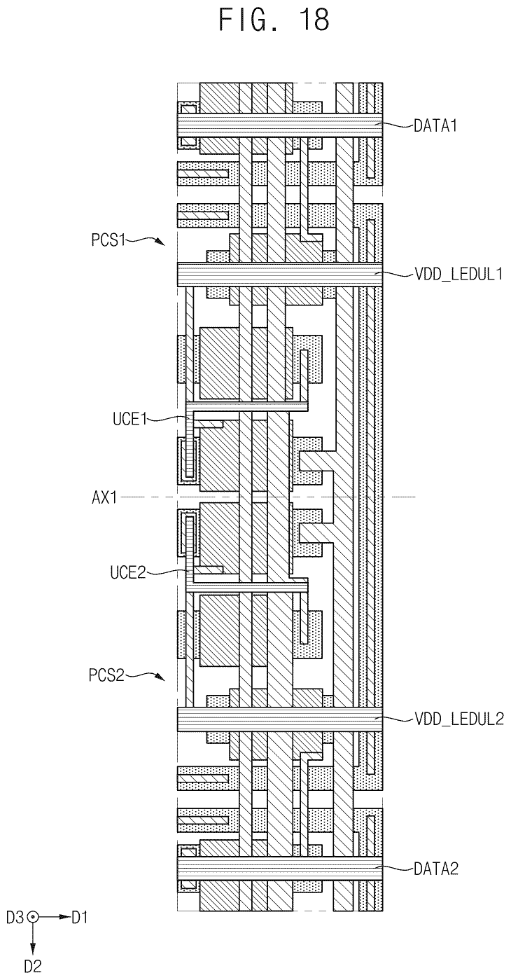

Referring to FIG. 18, a first data voltage line DATA1, a second data voltage line DATA2, a first upper high power voltage line VDD_LEDUL1, a second upper high power voltage line VDD_LEDUL2, and upper connecting electrodes. The upper connecting electrodes may include a first upper connecting electrode UCE1 and the second upper connecting electrode UCE2.

However, the first data voltage line DATA1, the second data voltage line DATA2, the first upper high power voltage line VDD_LEDUL1, the second upper high power voltage line VDD_LEDUL2, and the upper connecting electrodes may be substantially the same as the first data voltage line DATA1, the second data voltage line DATA2, the first upper high power voltage line VDD_LEDUL1, the second upper high power voltage line VDD_LEDUL2, and the upper connecting electrodes described with reference to FIG. 10.

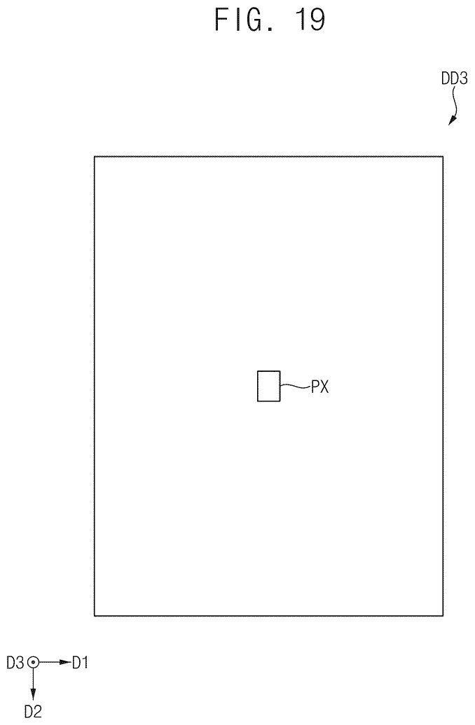

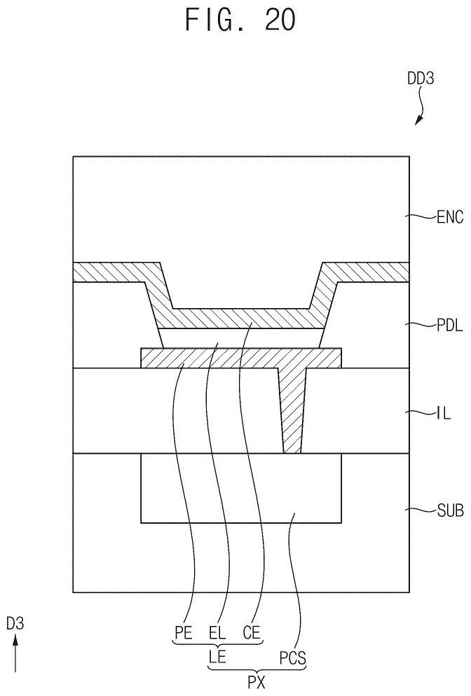

FIG. 19 is a plan view illustrating a pixel circuit structure and a guard trace included in a display device according to still another embodiment of the present invention. FIG. 20 is a cross-sectional view illustrating the display device of FIG. 19.

Referring to FIGS. 19 and 20, a display device DD3 according to still another embodiment of the present invention may display an image in the third direction D3 through a display surface defined by the first direction D1 and the second direction D2.

The display device DD3 may include a substrate SUB, a pixel PX, an insulating layer IL, a pixel defining layer PDL, and an encapsulation layer ENC. The pixel PX may include a pixel circuit structure PCS and a light emitting diode structure LE, and the light emitting diode structure LE may include a pixel electrode PE, an emission layer EL, and a common electrode CE.

However, the display device DD3 may be substantially the same as the display device DD1 described with reference to FIGS. 1 and 2, except for the pixel circuit structure PCS.

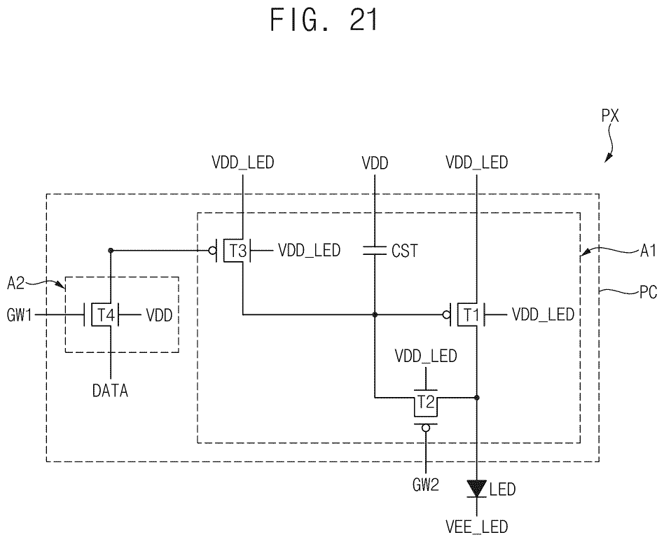

FIG. 21 is a circuit diagram illustrating a pixel included in the display device of FIG. 20.

Referring to FIG. 21, the pixel PX may include a pixel circuit PC and a light emitting diode LED. The pixel circuit PC may generate the driving current. The light emitting diode LED may be electrically connected to the pixel circuit PC and may emit light corresponding to the driving current.

The pixel circuit PC may include a first transistor T1, a second transistor T2, a third transistor T3, a fourth transistor T4, and a capacitor CST.

The first transistor T1 may include a gate terminal, a first terminal, a second terminal, and a back gate terminal. The gate terminal may be electrically connected to the capacitor CST, the first terminal may be electrically connected to a first high power voltage VDD_LED, and the second terminal may be electrically connected to the light emitting diode LED. The back gate terminal may receive the first high power voltage VDD_LED.

The second transistor T2 may include a gate terminal, a first terminal, a second terminal, and a back gate terminal. The gate terminal may be electrically connected to a second gate signal GW2, the first terminal may be electrically connected to the gate terminal of the first transistor T1, and the second terminal may be electrically connected to the second terminal of the first transistor T1. The back gate terminal may receive the first high power voltage VDD_LED.

The third transistor T3 may include a gate terminal, a first terminal, a second terminal, and a back gate terminal. The gate terminal may be electrically connected to the fourth transistor T4, the first terminal may receive the first high power voltage VDD_LED, and the second terminal may be electrically connected to the first transistor T1. The back gate terminal may receive the first high power voltage VDD_LED.

In an embodiment, each of the first to third transistors T1, T2, and T3 may be a PMOS transistor. However, the present invention is not limited thereto.

In an embodiment, the first transistor T1, the second transistor T2, and the third transistor T3 may be formed in a first area A1. For example, the first area A1 may be an area in which a PMOS transistor is formed. Accordingly, each of the first to third transistors T1, T2, and T3 may be a PMOS transistor.

The fourth transistor T4 may include a gate terminal, a first terminal, a second terminal, and a back gate terminal. The gate terminal may be electrically connected to a first gate signal GW1, the first terminal may be electrically connected to a data voltage DATA, and the second terminal may be electrically connected to the third transistor T3. The back gate terminal may be electrically connected to a second high power voltage VDD.

In an embodiment, the fourth transistor T4 may be an NMOS transistor. However, the present invention is not limited thereto.

In an embodiment, the fourth transistor T4 may be formed in the second area A2. For example, the second area A2 may be an area in which an NMOS transistor is formed. Accordingly, the fourth transistor T4 may be an NMOS transistor.

The capacitor CST may include a first terminal and a second terminal. The first terminal may be electrically connected to the second high power voltage VDD, and the second terminal may be electrically connected to the first transistor T1.

The light emitting diode LED may include a first terminal and a second terminal. The first terminal may be electrically connected to the first transistor T1, and the second terminal may be electrically connected to a low power voltage VEE_LED.

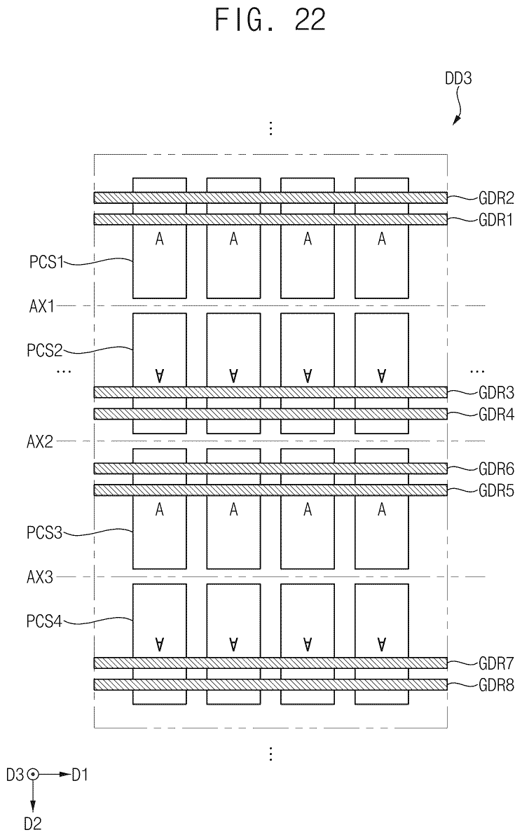

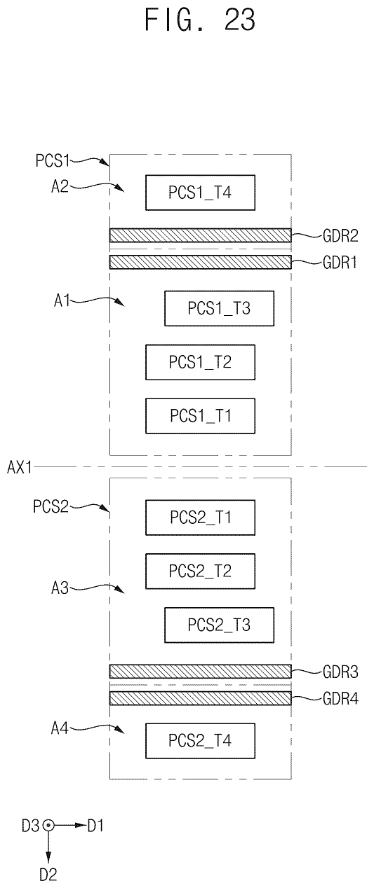

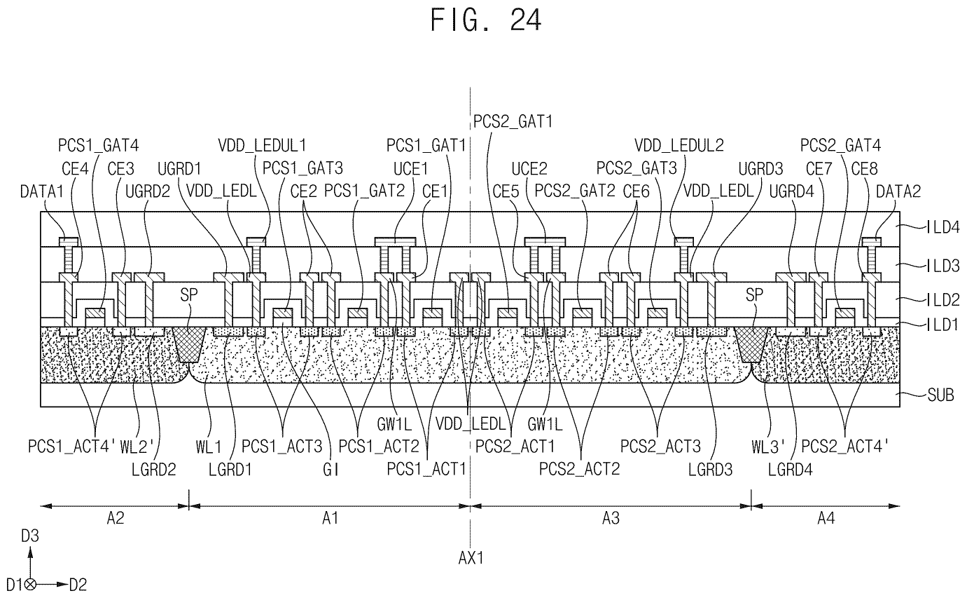

FIG. 22 is a plan view illustrating a pixel circuit structure and a guard trace included in the display device of FIG. 20. FIG. 23 is a plan view illustrating a first pixel circuit structure, a second pixel circuit structure, and a guard trace illustrated in FIG. 22. FIG. 24 is a cross-sectional view illustrating the first pixel circuit structure, the second pixel circuit structure, and the guard trace illustrated in FIG. 23.

Referring to FIG. 22, the display device DD3 may include a plurality of pixel circuit structures and a plurality of guard traces.

For example, the display device DD3 may include a first pixel circuit structure PCS1, a second pixel circuit structure PCS2, a third pixel circuit structure PCS3, and a fourth pixel circuit structure PCS4. The pixel circuit structures may be arranged in a matrix shape along the first direction D1 and the second direction D2.

For example, the display device DD3 may include a first guard trace GDR1, a second guard trace GDR2, a third guard trace GDR3, a fourth guard trace GDR4, a fifth guard trace GDR5, a sixth guard trace GDR6, a seventh guard trace GDR7, and an eighth guard trace GDR8. Each of the guard traces may extend along the first direction D1 and be arranged side by side in the second direction D2.

The second pixel circuit structure PCS2 may be adjacent to the first pixel circuit structure PCS1 in the second direction D2, the third pixel circuit structure PCS3 may be adjacent to the second pixel circuit structure PCS2 in the second direction D2, and the fourth pixel circuit structure PCS4 may be adjacent to the third pixel circuit structure PCS3 in the second direction D2.

In an embodiment, the second pixel circuit structure PCS2 may be symmetrical with the first pixel circuit structure PCS1. For example, the second pixel circuit structure PCS2 may be plane-symmetrical with the first pixel circuit structure PCS1 with respect to a first symmetry plane AX1 extending in the first direction D1 and the third direction D3.

In an embodiment, the third pixel circuit structure PCS3 may be symmetrical with the second pixel circuit structure PCS2. For example, the third pixel circuit structure PCS3 may be plane-symmetrical with the second pixel circuit structure PCS2 with respect to a second symmetry plane AX2 extending in the first direction D1 and the third direction D3.

In embodiment, the fourth pixel circuit structure PCS4 may be symmetrical with the third pixel circuit structure PCS3. For example, the fourth pixel circuit structure PCS4 may be plane-symmetrical with the third pixel circuit structure PCS3 with respect to a third symmetry plane AX3 extending in the first direction D1 and the third direction D3.

Referring to FIG. 23, the first pixel circuit structure PCS1 may include a 1-1 transistor PCS1_T1, a 1-2 transistor PCS1_T2, a 1-3 transistor PCS1_T3, and a 1-4 transistor PCS1_T4. In an embodiment, the 1-1 transistor PCS1_T1, the 1-2 transistor PCS1_T2, and the 1-3 transistor PCS1_T3 may correspond to the first to third transistors T1, T2, and T3 described with reference to FIG. 21, respectively. The 1-4 transistor PCS1_T4 may correspond to the fourth transistor T4 described with reference to FIG. 21.

The first pixel circuit structure PCS1 may be divided into the first area A1 and the second area A2 adjacent to the first area A1. The 1-1 transistor PCS1_T1, the 1-2 transistor PCS1_T2, and the 1-3 transistor PCS1_T3 may be disposed in the first area A1. The 1-4 transistor PCS1_T4 may be disposed in the second area A2.

The first guard trace GDR1 may be disposed in the first area A1 and adjacent to the second area A2 and may be electrically connected to the first area A1 (e.g., first well WL1 in FIG. 24). Accordingly, the first high power voltage VDD_LED may be transmitted to the back gate terminal of the 1-1 transistor PCS1_T1, the back gate terminal of the 1-2 transistor PCS1_T2, the back gate terminal of the 1-3 transistor PCS1_T3, and the first guard trace GDR1.

The second guard trace GDR2 may be disposed in the second area A2 and adjacent to the first area A1 and may be electrically connected to the second area A2 (e.g., second well WL2′ in FIG. 24). Accordingly, the second high power voltage VDD may be transmitted to the back gate terminal of the 1-4 transistor PCS1_T4 and the second guard trace GDR2. While the first guard trace GDR1 and the second guard trace GDR2 are disposed in the first area A1 and the second area A2, respectively, they are not parts of the first pixel circuit structure PCS1.

The second pixel circuit structure PCS2 may include a 2-1 transistor PCS2_T1, a 2-2 transistor PCS2_T2, a 2-3 transistor PCS2_T3, and a 2-4 transistor PCS2_T4. In an embodiment, the 2-1 transistor PCS2_T1, the 2-2 transistor PCS2_T2, and the 2-3 transistor PCS2_T3 may correspond to the first to third transistors T1, T2, and T3 described with reference to FIG. 21, respectively. The 2-4 transistor PCS2_T4 may correspond to the fourth transistor T4 described with reference to FIG. 21.

The second pixel circuit structure PCS2 may be divided into a third area A3 and a fourth area A4 adjacent to the third area A3. The 2-1 transistor PCS2_T1, the 2-2 transistor PCS2_T2, and the 2-3 transistor PCS2_T3 may be disposed in the third area A3. The 2-4 transistor PCS2_T4 may be disposed in the fourth area A4.

The third guard trace GDR3 may be disposed in the third aera A3 and adjacent to the fourth area A4 and may be electrically connected to the third area A3 (e.g., first well WL1 in FIG. 24). Accordingly, the first high power voltage VDD_LED may be transmitted to the back gate terminal of the 2-1 transistor PCS2_T1, the back gate terminal of the 2-2 transistor PCS2_T2, the back gate terminal of the 2-3 transistor PCS2_T3, and the third guard trace GDR3.

The fourth guard trace GDR4 may be disposed in the fourth area A4 and adjacent to the third area A3 and may be electrically connected to the second area A4 (e.g., third well WL3′ in FIG. 24). Accordingly, the second high power voltage VDD may be transmitted to the back gate terminal of the 2-4 transistor PCS2_T4 and the fourth guard trace GDR4. While the third guard trace GDR3 and the fourth guard trace GDR4 are disposed in the third area A3 and the fourth area A4, respectively, they are not parts of the second pixel circuit structure PCS2.

In an embodiment, the 1-1 transistor PCS1_T1 may be plane-symmetrical with the 2-1 transistor PCS2_T1 with respect to the first symmetry plane AX1. The 1-2 transistor PCS1_T2 may be plane-symmetrical with the 2-2 transistor PCS2_T2 with respect to the first symmetry plane AX1. The 1-3 transistor PCS1_T3 may be plane-symmetrical with the 2-3 transistor PCS2_T3 with respect to the first symmetry plane AX1. The 1-4 transistor PCS1_T4 may be plane-symmetrical with the 2-4 transistor PCS2_T4 with respect to the first symmetry plane AX1.

In an embodiment, the first guard trace GDR1 and the third guard trace GDR3 may face each other, and no guard trace may be disposed between the first guard trace GDR1 and the third guard trace GDR3. In other words, the first area A1 and the third area A3 may be connected to each other, and no guard trace extending in the first direction D1 may be disposed at a border between the first area A1 and the third area A3. Accordingly, the distance in the second direction D2 between the first pixel circuit structure PCS1 and the second pixel circuit structure PCS2 may be shortened, and the resolution of the display device DD3 may be effectively improved.

Referring to FIG. 24, in an embodiment, PMOS transistors may be formed in the first and third areas A1 and A3. Accordingly, the first well WL1 may be formed by doping an impurity, such as phosphorus, that imparts n-type conductivity to the substrate SUB overlapping the first and third areas A1 and A3. In addition, a 1-1 active pattern PCS1_ACT1, a 1-2 active pattern PCS1_ACT2, a 1-3 active pattern PCS1_ACT3, a 2-1 active pattern PCS2_ACT1, a 2-2 active pattern PCS2_ACT2, and a 2-3 active pattern PCS2_ACT3, formed in the first and third areas A1 and A3, may include an impurity, such as boron, that imparts p-type conductivity.

In an embodiment, NMOS transistors may be formed in the second and fourth areas A2 and A4. Accordingly, a second well WL2′ and a third well WL3′ may be formed by doping an impurity, such as boron, that imparts p-type conductivity to the substrate SUB overlapping the second and fourth areas A2 and A4. In addition, a 1-4 active pattern PCS1_ACT4′ and the 2-4 active pattern PCS2_ACT4′, formed in the second and fourth areas A2 and A4, may include an impurity, such as phosphorus, that imparts n-type conductivity.

The display devices DD1, DD2, and DD3 according to embodiments of the present invention may include a first pixel circuit structure PCS1 and a second pixel circuit structure PCS2. The second pixel circuit structure PCS2 may be adjacent to the first pixel circuit structure PCS1 in the second direction D2. In an embodiment, the second pixel circuit structure PCS2 may be plane-symmetrical with the first pixel circuit structure PCS1 with respect to a first symmetry plane AX1 that is parallel to the first direction D1 and the third direction D3.

Since the second pixel circuit structure PCS2 is symmetrical with the first pixel circuit structure PCS1 with respect to the first symmetry plane AX1, the first area A1 of the first pixel circuit structure PCS1 and the third area A3 of the second pixel circuit structure PCS2 may be connected to each other. Accordingly, the first well WL1 may be formed continuously in the first and third areas A1 and A3. In other words, the first well WL1 may not be separated. Accordingly, no guard trace extending in the first direction D1 may be arranged at a border between the first and second pixel circuit structures PCS1, PCS2, and the distance in the second direction D2 between the first pixel circuit structure PCS1 and the second pixel circuit structure PCS2 may be shortened. Accordingly, the resolution of the display devices DD1, DD2, and DD3 may be effectively improved.

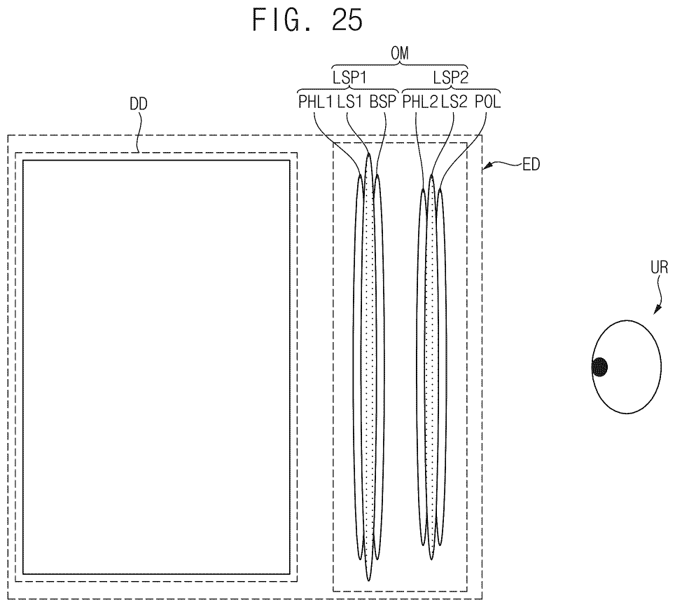

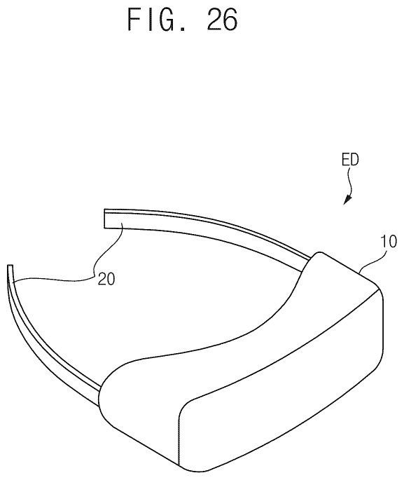

FIG. 25 is a diagram illustrating an electronic device including a display device of the present invention. FIG. 26 is a perspective view illustrating an electronic device including a display device of the present invention.

Referring to FIG. 25, an electronic device ED may include a display device DD and an optical member OM. The optical member OM may be disposed in a path of light emitted from the display device DD and may refract the light to provide it to a user UR. The optical member OM may make the light emitted from the display device DD appear wider.

In an embodiment, the optical member OM may include a first lens part LSP1 and a second lens part LSP2. The first lens part LSP1 may include a first lens LS1, a first phase retardation layer PHL1, and a beam splitter BSP. The second lens part LSP2 may include a second lens LS2, a second phase retardation layer PHL2, and a polarizing plate POL.

The first lens LS1 and the second lens LS2 may be curved lenses. The curves of the first lens LS1 and the second lens LS2 may be spherical or aspherical. For example, each of the first lens LS1 and the second lens LS2 may include glass or PMMA (polymethyl methacrylate).

The first phase retardation layer PHL1 may be disposed on one side of the first lens LS1. For example, the first phase retardation layer PHL1 may be disposed on the side of the first lens LS1 facing the display panel PNL. The first phase retardation layer PHL1 may have a delay axis and provide a phase difference with respect to a retardation axis. For example, the first phase retardation layer PHL1 may provide a phase difference of λ/4 or 3λ/4. Accordingly, the first phase retardation layer PHL1 may delay light in the direction of the retardation axis by λ/4 or 3λ/4 to convert linear polarization into circular polarization or circular polarization into linear polarization.

The beam splitter BSP may be disposed on one side of the first lens LS1. For example, the beam splitter BSP may be disposed on the side of the first lens LS1 facing the user UR. The beam splitter BSP may transmit some of the incident light and reflect some of the incident light. The beam splitter BSP may reflect and transmit light regardless of the polarization characteristics of the light. In an embodiment, the beam splitter BSP may include a semi-transparent metal material.

The second phase retardation layer PHL2 may be disposed on one side of the second lens LS2. For example, the second phase retardation layer PHL2 may be disposed on the side of the second lens LS2 facing the first lens part LSP1. The second phase retardation layer PHL2 may have a retardation axis and provide a phase difference with respect to the retardation axis. For example, the second phase retardation layer PHL2 may provide a phase difference of λ/4 or 3λ/4. Accordingly, the second phase retardation layer PHL2 may delay light in the direction of the retardation axis by λ/4 or 3λ/4 to convert linear polarization into circular polarization, or circular polarization into linear polarization.

The polarizing plate POL may be disposed on one side of the second lens LS2. For example, the polarizing plate POL may be placed on the side of the second lens LS2 facing the user UR.

In an embodiment, the polarizing plate POL may be a reflective polarizing plate. In this case, the polarizing plate POL may have a reflection axis. That is, the polarizing plate POL may reflect light of linear polarization in the same direction as the reflection axis. That is, light of linear polarization in the same direction as the reflection axis may not transmit the polarizing plate POL. In addition, the polarizing plate POL may transmit light of linear polarization perpendicular to the reflection axis. That is, the polarizing plate POL may have a transmission axis perpendicular to the reflection axis.

Referring to FIG. 26, the electronic device ED may include a storage part 10 and a glasses frame leg 20. For example, the electronic device ED may be implemented as a head mounted display. Hereinafter, the electronic device ED will be described as an example of the head mounted display.

The electronic device ED including the display device DD and the optical member OM may be stored in the storage part 10.

The electronic device ED may provide an image displayed on the display device DD stored in the storage part 10 to the user through an eyepiece, etc. Accordingly, the electronic device ED may provide a virtual image to the user. That is, the electronic device ED may implement virtual reality (VR) or augmented reality (AR).

The glasses frame legs 20 may be configured so that the user can easily put them on or take them off. However, the present invention is not necessarily limited thereto, and the electronic device ED may also include a head-mounted band that can be mounted on the head.

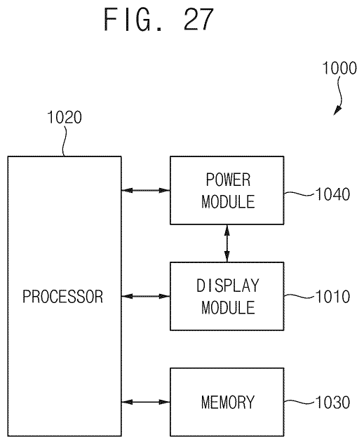

FIG. 27 is a block diagram illustrating an electronic device according to an embodiment of the present invention.

Referring to FIG. 27, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

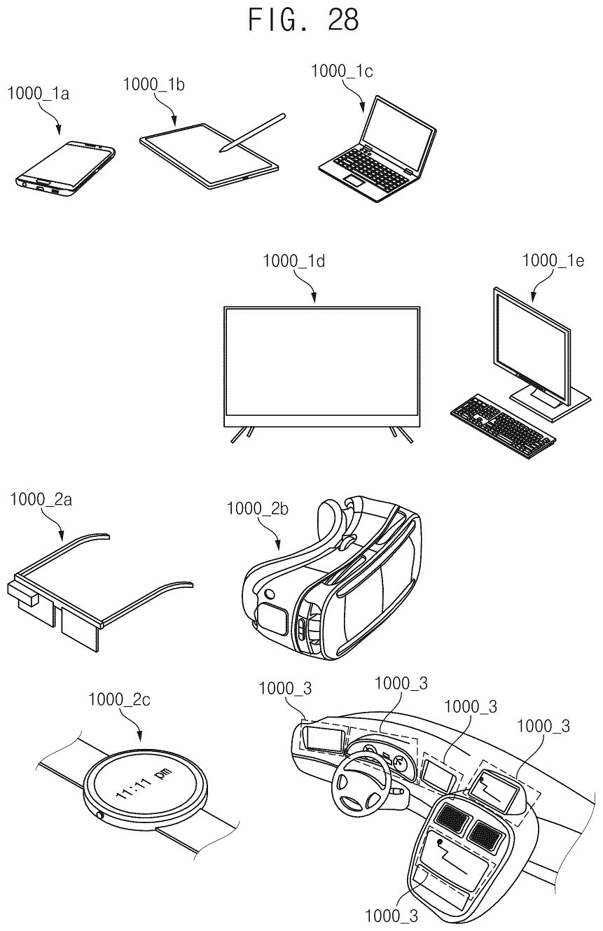

FIG. 28 is a schematic diagram of an electronic device according to embodiments of the present invention.

Referring to FIG. 28, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a first pixel circuit structure divided into a first area and a second area adjacent to the first area;
a first guard trace electrically connected to the first area of the first pixel circuit structure and extending in a first direction;
a second guard trace electrically connected to the second area of the first pixel circuit structure and extending in the first direction;
a second pixel circuit structure adjacent to the first pixel circuit structure in a second direction intersecting the first direction, divided into a third area extending from the first area and a fourth area adjacent to the third area, and symmetrical to the first pixel circuit structure;
a third guard trace electrically connected to the third area of the second pixel circuit structure and extending in the first direction; and
a fourth guard trace electrically connected to the fourth area of the second pixel circuit structure and extending in the first direction.

2. The display device of claim 1, wherein the second pixel circuit structure is plane-symmetrical with the first pixel circuit structure with respect to a symmetry plane extending in the first direction and perpendicular to the second direction.

3. The display device of claim 1, wherein no guard trace extending in the first direction is disposed between the first guard trace and the third guard trace.

4. The display device of claim 1, wherein no guard trace extending in the first direction is disposed at a border between the first area and the third area.

5. The display device of claim 1, wherein the first guard trace is disposed in the first area and adjacent to the second area.

6. The display device of claim 5, wherein the second guard trace is disposed in the second area and adjacent to the first area.

7. The display device of claim 6, wherein the third guard trace is disposed in the third area and adjacent to the fourth area, and
the fourth guard trace is disposed in the fourth area and adjacent to the third area.

8. The display device of claim 1, wherein the first pixel circuit structure includes a 1-1 transistor, a 1-2 transistor, a 1-3 transistor, and a 1-4 transistor,
the 1-1 transistor, the 1-2 transistor, and the 1-3 transistor are disposed in the first area, and
the 1-4 transistor is disposed in the second area.

9. The display device of claim 8, wherein the second pixel circuit structure includes a 2-1 transistor, a 2-2 transistor, a 2-3 transistor, and a 2-4 transistor,
the 2-1 transistor, the 2-2 transistor, and the 2-3 transistor are disposed in the third area, and
the 2-4 transistor is disposed in the fourth area.

10. The display device of claim 9, wherein the 1-1 transistor is symmetrical to the 2-1 transistor,
the 1-2 transistor is symmetrical to the 2-2 transistor,
the 1-3 transistor is symmetrical to the 2-3 transistor, and
the 1-4 transistor is symmetrical to the 2-4 transistor.

11. The display device of claim 8, wherein a first high power voltage is provided to a back gate terminal of each of the 1-1 transistor, the 1-2 transistor, and the 1-3 transistor, and
a second high power voltage different from the first high power voltage is provided to a back gate terminal of the 1-4 transistor.

12. The display device of claim 11, wherein the first high power voltage is transmitted to the first guard trace through the first area, and
the second high power voltage is transmitted to the second guard trace through the second area.

13. The display device of claim 8, wherein the 1-1 transistor, the 1-2 transistor, and the 1-3 transistor are p-channel metal-oxide-semiconductor (PMOS) transistors, and
the 1-4 transistor is an n-channel metal-oxide-semiconductor (NMOS) transistor.

14. The display device of claim 1, further comprising:
a connecting guard trace electrically connecting the first guard trace and the third guard trace and extending in the second direction.

15. The display device of claim 1, wherein the first pixel circuit structure includes:
active patterns disposed on a substrate; and
connecting electrodes disposed on the active patterns and connected to the active patterns, and
wherein the first guard trace includes:
a lower guard trace disposed in a same layer as the active patterns; and
an upper guard trace disposed in a same layer as the connecting electrodes and connected to the first lower guard trace.

16. The display device of claim 15, wherein the lower guard trace extends in the first direction.

17. The display device of claim 16, wherein the upper guard trace is disposed in an island shape and contacts the lower guard trace through a contact hole.

18. The display device of claim 1, further comprising:
a third pixel circuit structure adjacent to the second pixel circuit structure in the second direction and symmetrical to the second pixel circuit structure.

19. An electronic device comprising:
a first pixel circuit structure divided into a first area and a second area adjacent to the first area;
a first guard trace electrically connected to the first area of the first pixel circuit structure and extending in a first direction;
a second guard trace electrically connected to the second area of the first pixel circuit structure and extending in the first direction;
a second pixel circuit structure adjacent to the first pixel circuit structure in a second direction intersecting the first direction, divided into a third area extending from the first area and a fourth area adjacent to the third area, and symmetrical to the first pixel circuit structure;
a third guard trace electrically connected to the third area of the second pixel circuit structure and extending in the first direction; and
a fourth guard trace electrically connected to the fourth area of the second pixel circuit structure and extending in the first direction.
